(19) United States
(12) Patent Application Publication
(10) Pub. No.: US 2025/0318188 A1
(43) Pub. Date: Oct. 9, 2025

(54) SEMICONDUCTOR DEVICE AND METHOD OF FABRICATING THE SAME

(71) Applicant: Samsung Electronics Co., Ltd., Suwon-si (KR)

(72) Inventors: Hyunjun LIM, Suwon-si (KR); Taehan KIM, Suwon-si (KR); Jiwon PARK, Suwon-si (KR); Won-Sun YANG, Suwon-si (KR); Jun-Youp LEE, Suwon-si (KR); Jinyoung CHOI, Suwon-si (KR)

(73) Assignee: Samsung Electronics Co., Ltd., Suwon-si (KR)

(21) Appl. No.: 18/934,424

(22) Filed: Nov. 1, 2024

(30) Foreign Application Priority Data
Apr. 3, 2024 (KR) 10-2024-0045497

(51) Int. Cl. H01L 29/417; H01L 23/528; H01L 29/06; H01L 29/08; H01L 29/423; H01L 29/66; H01L 29/775; H01L 29/786

(52) U.S. Cl. CPC H10D 30/6729; H01L 23/5286; H10D 30/014; H10D 30/43; H10D 30/6735; H10D 30/6757; H10D 62/121; H10D 62/151; H10D 64/017

(57) ABSTRACT

A semiconductor device may include a substrate including an active pattern, a source/drain pattern on the substrate, and a blocking pattern between the active pattern and the source/drain pattern. A top surface of the blocking pattern may be in contact with a bottom surface of the source/drain pattern. The bottom surface of the source/drain pattern may have a first width in a first direction, and the top surface of the blocking pattern may have a second width in the first direction. The second width may be larger than the first width.

### CROSS-REFERENCE TO RELATED APPLICATIONS

This U.S. non-provisional patent application claims priority under 35 U.S.C. § 119 to Korean Patent Application No. 10-2024-0045497, filed on Apr. 3, 2024, in the Korean Intellectual Property Office, the entire contents of which are hereby incorporated by reference.

### BACKGROUND

The present inventive concepts relate to semiconductor devices and methods of fabricating the same, and in particular, to semiconductor devices including a field effect transistor and methods of fabricating the same.

A semiconductor device includes an integrated circuit composed of metal-oxide-semiconductor field-effect transistors (MOS-FETs). To meet an increasing demand for a semiconductor device with a small pattern size and a reduced design rule, the MOS-FETs are being aggressively scaled down. The scale-down of the MOS-FETs may lead to deterioration in operational properties of the semiconductor device. A variety of studies are being conducted to overcome technical limitations associated with the scale-down of the semiconductor device and to realize the semiconductor devices with high performance.

### SUMMARY

Some example embodiments of the inventive concepts provide semiconductor devices with improved electrical and reliability characteristics.

Some example embodiments of the inventive concepts provide methods of fabricating a semiconductor device with improved electrical and reliability characteristics.

According to an example embodiment of the inventive concepts, a semiconductor device may include a substrate including an active pattern, a source/drain pattern on the substrate, and a blocking pattern between the active pattern and the source/drain pattern. A top surface of the blocking pattern may be in contact with a bottom surface of the source/drain pattern. The bottom surface of the source/drain pattern may have a first width in a first direction, and the top surface of the blocking pattern may have a second width in the first direction. The second width may be larger than the first width.

According to an example embodiment of the inventive concepts, a semiconductor device may include a substrate including an active pattern, a channel pattern on the active pattern, the channel pattern including a plurality of semiconductor patterns, the semiconductor patterns stacked to be spaced apart from each other, the semiconductor patterns including a first semiconductor pattern and a second semiconductor pattern, is the first semiconductor pattern being a lowermost one of the semiconductor patterns, the second semiconductor pattern being adjacent to the first semiconductor pattern, a lower power line buried in a lower portion of the substrate, a source/drain pattern on the substrate, a gate electrode on the semiconductor patterns, the gate electrode including a first inner gate electrode between the first semiconductor pattern and the second semiconductor pattern, a first inner gate insulating layer interposed between the first inner gate electrode and the source/drain pattern, and a blocking pattern between the active pattern and the source/drain pattern. At least a portion of a top surface of the blocking pattern may be in direct contact with the first inner gate insulating layer.

According to an example embodiment of the inventive concepts, a semiconductor device may include an insulating substrate, a channel pattern on the insulating substrate, the channel pattern including a plurality of semiconductor patterns, the semiconductor patterns stacked to be spaced apart from each other, a source/drain pattern connected to the channel pattern, a gate electrode on the channel pattern, a gate insulating layer interposed between the gate electrode and the channel pattern, a gate spacer on a side surface of the gate electrode, a gate capping pattern on a top surface of the gate electrode, an interlayer insulating layer covering the source/drain pattern and the gate capping pattern, a gate contact penetrating the interlayer insulating layer and the gate capping pattern, the gate contact electrically connected to the gate electrode, a first metal layer on the interlayer insulating layer, the first metal layer including a first interconnection line electrically connected to the gate contact, a lower power line in a lower portion of the insulating substrate, a back-side contact penetrating the insulating substrate and electrically connecting the lower power line to the source/drain pattern, and a blocking pattern between the insulating substrate and the source/drain pattern. A top surface of the blocking pattern may be in contact with a bottom surface of the source/drain pattern, and a width of the top surface of the blocking pattern may be larger than a width of the bottom surface of the source/drain pattern.

### BRIEF DESCRIPTION OF THE DRAWINGS

FIGS. 1 to 3 are conceptual diagrams illustrating logic cells in a semiconductor device according to some example embodiments of the inventive concepts.

FIG. 4 is a plan view illustrating a semiconductor device according to an example embodiment of the inventive concepts.

FIGS. 5A to 5E are sectional views taken along lines A-A′, B-B′, C-C′, D-D′, and E-E′ of FIG. 4.

FIG. 6A is an enlarged sectional view illustrating a portion ‘M’ of FIG. 5B.

FIG. 6B is an enlarged sectional view illustrating a portion ‘N’ of FIG. 5B.

FIG. 7 is an enlarged sectional view illustrating another example of the portion ‘N’ of FIG. 5B.

FIGS. 8A to 10C and FIGS. 16A to 21B are sectional views illustrating a method of fabricating a semiconductor device, according to an example embodiment of the inventive concepts.

FIGS. 11 to 15 are enlarged views illustrating the portions ‘M’ and ‘N’ of FIG. 5A and illustrating a method of fabricating the semiconductor device of FIGS. 6A and 6B.

### DETAILED DESCRIPTION

Example embodiments of the inventive concepts will now be described more fully with reference to the accompanying drawings, in which some example embodiments are shown.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

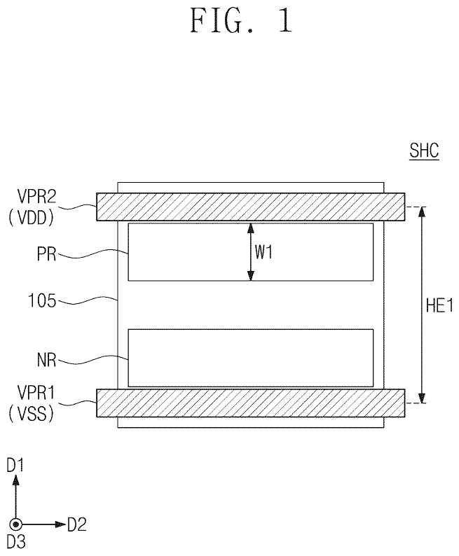

FIGS. 1 to 3 are conceptual diagrams illustrating logic cells in a semiconductor device according to some example embodiments of the inventive concepts.

Referring to FIG. 1, a single height cell SHC may be provided. For example, a first power line M1_R1 and a second power line M1_R2 may be provided on a substrate 105. The first power line M1_R1 may be a conduction path, to which a drain voltage VDD (e.g., a power voltage) is provided. The second power line M1_R2 may be a conduction path, to which a source voltage VSS (e.g., a ground voltage) is provided.

The single height cell SHC may be defined between the first lower power line VPR1 and the second lower power line VPR2. The single height cell SHC may include one PMOSFET region PR and one NMOSFET region NR. In other words, the single height cell SHC may have a CMOS structure provided between the first lower power line VPR1 and the second lower power line VPR2.

Each of the PMOSFET and NMOSFET regions PR and NR may have a first width in a first direction D1. A length of the single height cell SHC in the first direction D1 may be defined as a first height HE1. The first height HE1 may be substantially equal to a distance (e.g., pitch) between the first lower power line VPR1 and the second lower power line VPR2.

The single height cell SHC may constitute a single logic cell. In the present specification, the logic cell may mean a logic device (e.g., AND, OR, XOR, XNOR, inverter, and so forth), which is configured to execute a specific function. In other words, the logic cell may include transistors constituting the logic device and interconnection lines connecting the transistors to each other.

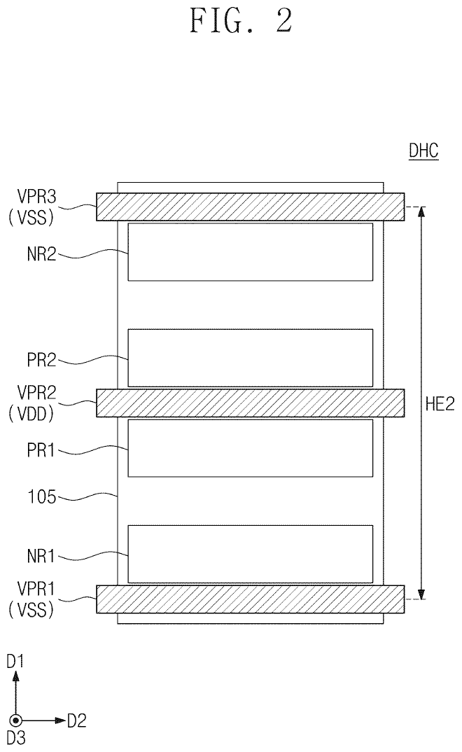

Referring to FIG. 2, a double height cell DHC may be provided. For example, a first lower power line VPR1, a second lower power line VPR2, and a third lower power line VPR3 may be provided on a substrate 105. The second lower power line VPR2 may be disposed between the first lower power line VPR1 and the third lower power line VPR3. The third lower power line VPR3 may be a conduction path, to which the source voltage VSS is provided.

The double height cell DHC may be defined between the first lower power line VPR1 and the third lower power line VPR3. The double height cell DHC may include a first PMOSFET region PR1, a second PMOSFET region PR2, a first NMOSFET region NR1, and a second NMOSFET region NR2.

The first NMOSFET region NR1 may be adjacent to the first lower power line VPR1. The second NMOSFET region NR2 may be adjacent to the third lower power line VPR3. The first and second PMOSFET regions PR1 and PR2 may be adjacent to the second lower power line VPR2. When viewed in a plan view, the second lower power line VPR2 may be disposed between the first and second PMOSFET regions PR1 and PR2.

A length of the double height cell DHC in the first direction D1 may be defined as a second height HE2. The second height HE2 may be about two times the first height HE1 of FIG. 1. The first and second PMOSFET regions PR1 and PR2 of the double height cell DHC may be combined to serve as a single PMOSFET region. Thus, a channel size of the PMOS transistor of the double height cell DHC may be larger than a channel size of the PMOS transistor of the single height cell SHC of FIG. 1.

For example, the channel size of the PMOS transistor of the double height cell DHC may be about two times the channel size of the PMOS transistor of the single height cell SHC. In this case, the double height cell DHC may be operated at a higher speed than the single height cell SHC. In an example embodiment, the double height cell DHC shown in FIG. 2 may be defined as a multi-height cell. Although not shown, the multi-height cell may include a triple height cell whose cell height is about three times that of the single height cell SHC.

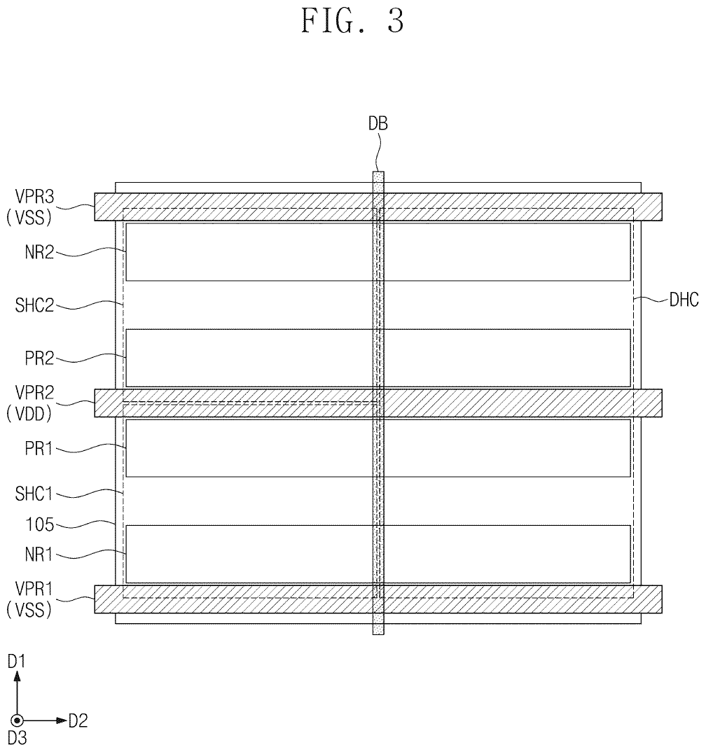

Referring to FIG. 3, a first single height cell SHC1, a second single height cell SHC2, and a double height cell DHC may be two-dimensionally disposed on a substrate 105. The first single height cell SHC1 may be disposed between the first and second lower power lines VPR1 and VPR2. The second single height cell SHC2 may be disposed between the second and third lower power lines VPR2 and VPR3. The second single height cell SHC2 may be adjacent to the first single height cell SHC1 in the first direction D1.

The double height cell DHC may be disposed between the first and third lower power lines VPR1 and VPR3. The double height cell DHC may be adjacent to the first and second single height cells SHC1 and SHC2 in a second direction D2.

A division structure DB may be provided between the first single height cell SHC1 and the double height cell DHC and between the second single height cell SHC2 and the double height cell DHC. An active region of the double height cell DHC may be electrically disconnected from an active region of each of the first and second single height cells SHC1 and SHC2 by the division structure DB.

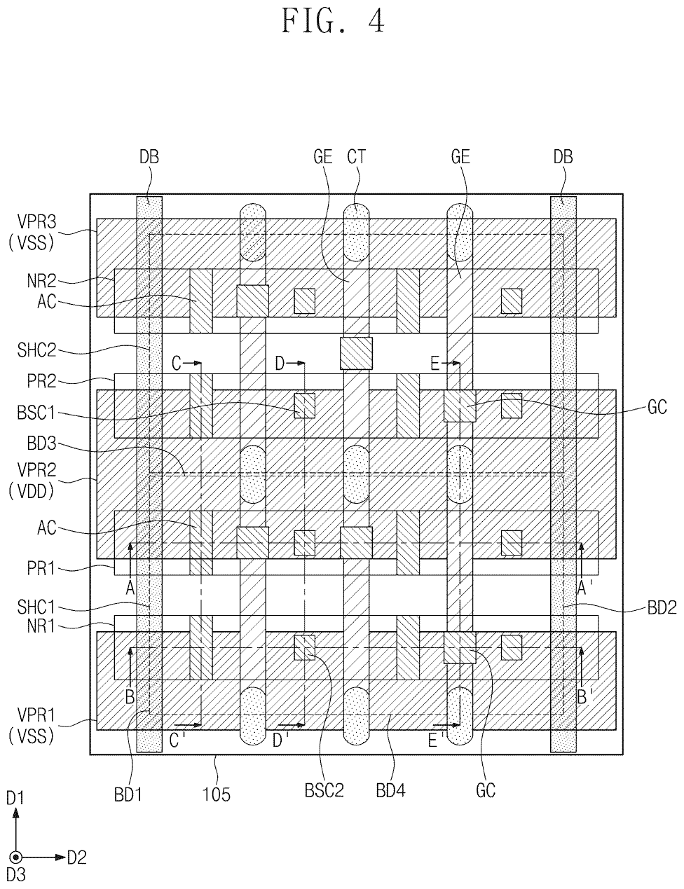

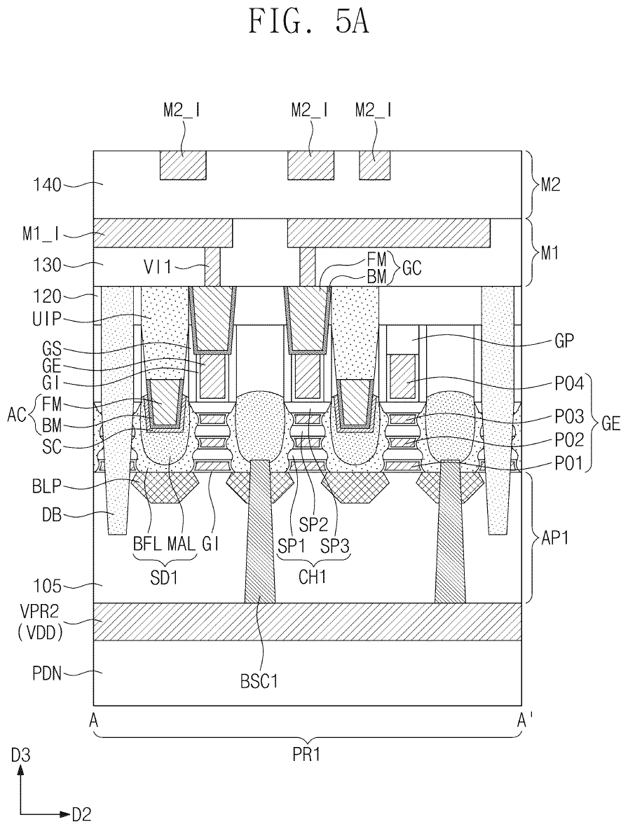

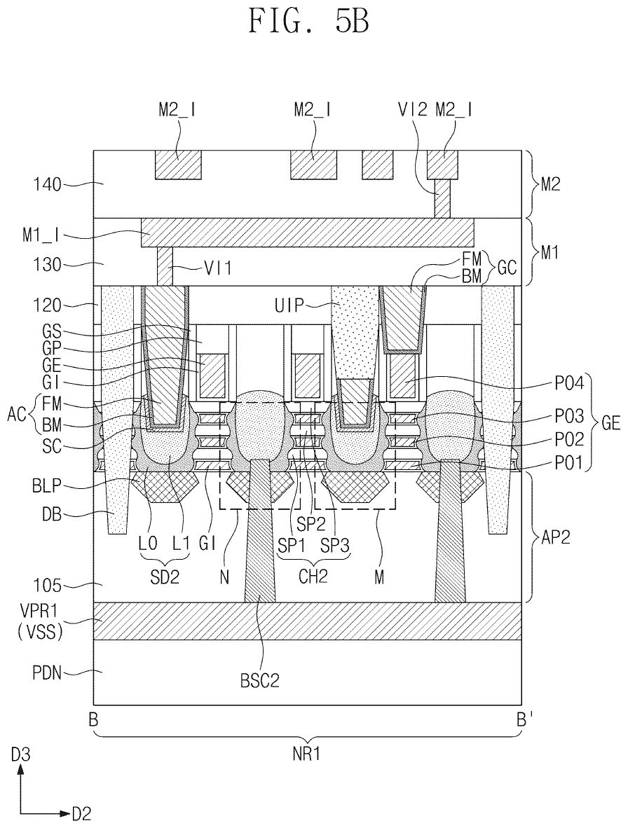

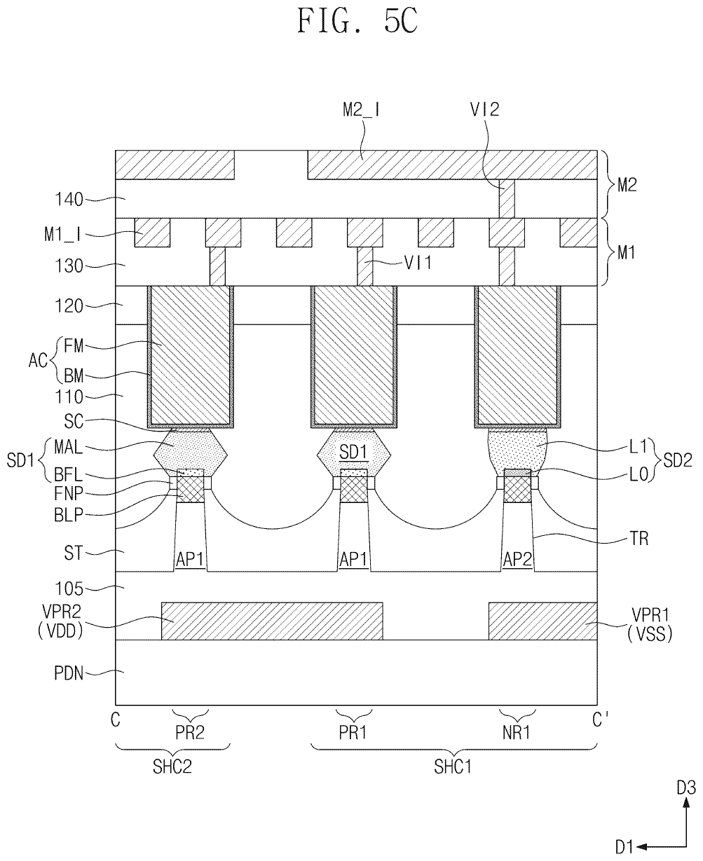

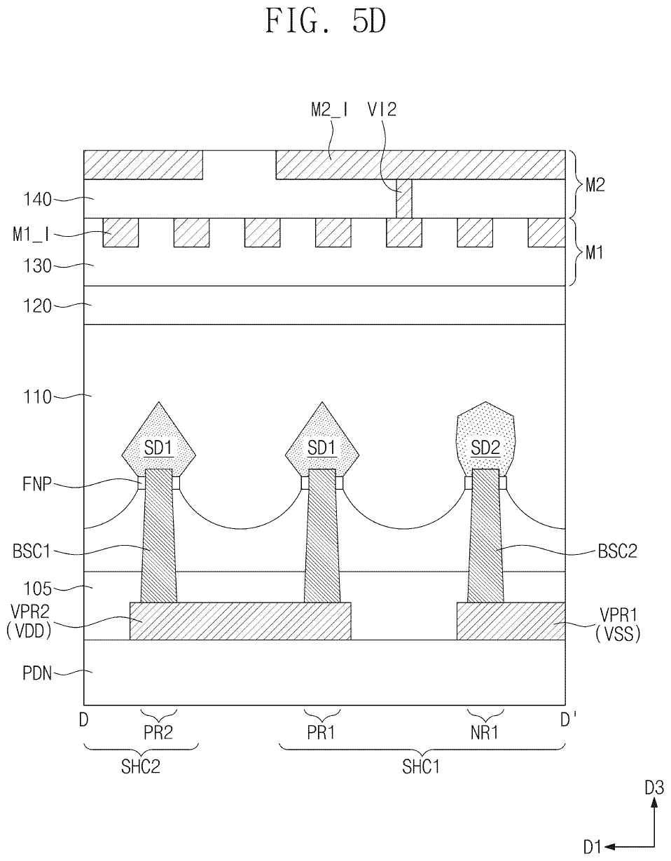

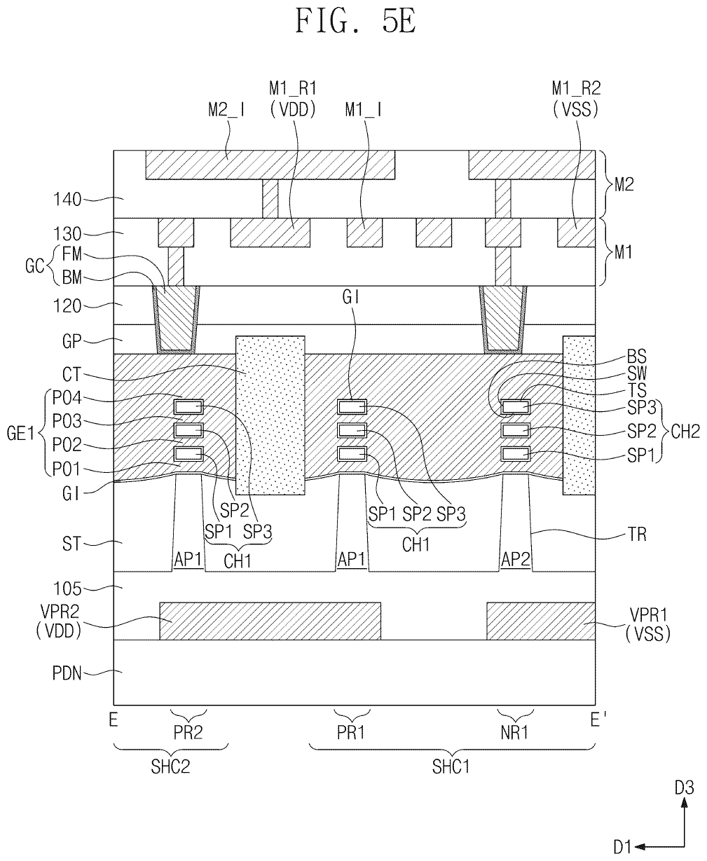

FIG. 4 is a plan view illustrating a semiconductor device according to an example embodiment of the inventive concepts. FIGS. 5A to 5E are sectional views taken along lines A-A′, B-B′, C-C′, D-D′, and E-E′ of FIG. 4. FIGS. 4 and 5A to 5D illustrate an example of a detailed structure of the first and second single height cells SHC1 and SHC2 of FIG. 3.

Referring to FIG. 4 and FIGS. 5A to 5E, the first and second single height cells SHC1 and SHC2 may be provided on the substrate 105. Logic transistors constituting a logic circuit may be disposed on each of the first and second single height cells SHC1 and SHC2. The substrate 105 may include a silicon-based insulating layer. For example, the substrate 105 may be an insulating substrate. For example, the substrate 105 may include a silicon oxide layer, a silicon nitride layer, or a silicon oxynitride layer. Lower power lines VPR1 to VPR3, which will be described below, may be disposed in the insulating layer of the substrate 105.

The substrate 105 may have the first PMOSFET region PR1, the second PMOSFET region PR2, the first NMOSFET region NR1, and the second NMOSFET region NR2. Each of the first PMOSFET region PR1, the second PMOSFET region PR2, the first NMOSFET region NR1, and the second NMOSFET region NR2 may be extended in the second direction D2. The first single height cell SHC1 may include the first NMOSFET region NR1 and the first PMOSFET region PR1, and the second single height cell SHC2 may include the second PMOSFET region PR2 and the second NMOSFET region NR2.

A first active pattern AP1 and a second active pattern AP2 may be defined by a trench TR, which is formed in an upper portion of the substrate 105. The first active pattern AP1 may be provided on each of the first and second PMOSFET regions PR1 and PR2. The second active pattern AP2 may be provided on each of the first and second NMOSFET regions NR1 and NR2. The first and second active patterns AP1 and AP2 may be extended in the second direction D2. Each of the first and second active patterns AP1 and AP2 may be a vertically-protruding portion of the substrate 105.

A device isolation layer ST may be provided to fill the trench TR. The device isolation layer ST may cover a side surface of each of the first and second active patterns AP1 and AP2. The device isolation layer ST may include a silicon oxide layer. The device isolation layer ST may not cover first and second channel patterns CH1 and CH2 to be described below.

The first channel pattern CH1 may be provided on the first active pattern AP1. The second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in a vertical direction (e.g., a third direction D3).

Each of the first to third semiconductor patterns SP1, SP2, and SP3 may be formed of or include at least one of silicon (Si), germanium (Ge), or silicon germanium (SiGe). For example, each of the first to third semiconductor patterns SP1, SP2, and SP3 may be formed of or include crystalline silicon. In an example embodiment, each of the first to third semiconductor patterns SP1, SP2, and SP3 may be a nanosheet.

A plurality of first source/drain patterns SD1 may be provided on the first active pattern AP1. A plurality of first recesses may be formed in an upper portion of the first active pattern AP1. The first source/drain patterns SD1 may be provided in the first recesses, respectively. The first source/drain patterns SD1 may be impurity regions of a first conductivity type (e.g., p-type). The first channel pattern CH1 may be interposed between each pair of the first source/drain patterns SD1. In other words, each pair of the first source/drain patterns SD1 may be connected to each other by the stacked first to third semiconductor patterns SP1, SP2, and SP3.

A plurality of second source/drain patterns SD2 may be provided on the second active pattern AP2. A plurality of second recesses may be formed in an upper portion of the second active pattern AP2. The second source/drain patterns SD2 may be provided in the second recesses, respectively. The second source/drain patterns SD2 may be impurity regions of a second conductivity type (e.g., n-type). The second channel pattern CH2 may be interposed between a pair of the second source/drain patterns SD2. In other words, each pair of the second source/drain patterns SD2 may be connected to each other by the stacked first to third semiconductor patterns SP1, SP2, and SP3.

The first and second source/drain patterns SD1 and SD2 may be epitaxial patterns, which are formed by a selective epitaxial growth (SEG) process. As an example, a top surface of each of the first and second source/drain patterns SD1 and SD2 may be positioned at substantially the same level as a top surface of the third semiconductor pattern SP3. However, in an example embodiment, the top surface of each of the first and second source/drain patterns SD1 and SD2 may be higher than the top surface of the third semiconductor pattern SP3.

The first source/drain patterns SD1 may be formed of or include a semiconductor material (e.g., SiGe) whose lattice constant is greater than that of the first channel pattern CH1. Accordingly, each pair of the first source/drain patterns SD1 may exert a compressive stress on the first channel pattern CH1 therebetween. The second source/drain patterns SD2 may be formed of or include the same semiconductor material (e.g., Si) as the second channel pattern CH2.

Each of the first source/drain patterns SD1 may include a buffer layer BFL and a main layer MAL on the buffer layer BFL. Referring back to FIG. 5A, the buffer layer BFL may cover an inner surface of a first recess RS1. The main layer MAL may fill an unfilled region of the first recess RS1 covered with the buffer layer BFL. The main layer MAL may have a volume that is larger than that of the buffer layer BFL. Each of the buffer and main layers BFL and MAL may be formed of or include silicon germanium (SiGe). For example, the buffer layer BFL may contain a relatively low concentration of germanium (Ge). In another example embodiment, the buffer layer BFL may contain only silicon (Si), without germanium (Ge). A germanium concentration of the buffer layer BFL may range from 0 at % to about 30 at %.

The main layer MAL may contain a relatively high concentration of germanium. In an example embodiment, the germanium concentration of the main layer MAL may range from about 30 at % to about 70 at %. The germanium concentration of the main layer MAL may increase in the third direction D3. For example, a portion of the main layer MAL, which is adjacent to the buffer layer BFL, may have a germanium concentration of about 40 at %, and an upper portion of the main layer MAL may have a germanium concentration of about 60 at %.

Each of the buffer and main layers BFL and MAL may contain an impurity (e.g., boron, gallium, or indium) that allows the first source/drain pattern SD1 to have a p-type conductivity. The impurity concentration of each of the buffer and main layers BFL and MAL may range from 1E18 atoms/cm³ to 5E22 atoms/cm³. The impurity concentration of the main layer MAL may be higher than the impurity concentration of the buffer layer BFL.

The buffer layer BFL may be used to protect the main layer MAL during replacing second semiconductor layers SAL with first to third inner electrodes PO1, PO2, and PO3 of a gate electrode GE, as will be described below. In other words, the buffer layer BFL may block or prevent an etchant material, which is used to remove the second semiconductor layers SAL, from entering and etching the main layer MAL.

Each of the second source/drain patterns SD2 may be formed of or include silicon (Si). The second source/drain pattern SD2 may further contain impurities (e.g., phosphorus, arsenic, or antimony) that allow the second source/drain pattern SD2 to have an n-type conductivity. The impurity concentration of the second source/drain pattern SD2 may range from 1E18 atom/cm³ to 5E22 atom/cm³.

In an example embodiment, the second source/drain patterns SD2 may include a first layer L0 and a second layer L1 on the first layer L0. A volume of the second layer L1 may be larger than a volume of the first layer L0. The first layer L0 may include silicon (Si). The second layer L1 may include a silicon-based material doped with impurities. For example, the impurity in the second layer L1 may be at least one of phosphorus, arsenic, or antimony.

Gate electrodes GE may be provided to cross the first and second channel patterns CH1 and CH2 and to extend in the first direction D1. The gate electrodes GE may be arranged at a first pitch in the second direction D2. Each of the gate electrodes GE may vertically overlap a corresponding one of the first and second channel patterns CH1 and CH2.

The gate electrode GE may include a first inner electrode PO1 interposed between the first or second active pattern AP1 or AP2 and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring back to FIG. 5E, the gate electrode GE may be provided on a top surface TS, a bottom surface BS, and opposite side surfaces SW of each of the first to third semiconductor patterns SP1, SP2, and SP3. That is, the transistor according to the present example embodiment may be a three-dimensional field effect transistor (e.g., MBCFET or GAAFET) in which the gate electrode GE is provided to three-dimensionally surround the channel pattern.

As an example, the first single height cell SHC1 may have a first border BD1 and a second border BD2, which are opposite to each other in the second direction D2. The first and second borders BD1 and BD2 may be extended in the first direction D1. The first single height cell SHC1 may have a third border BD3 and a fourth border BD4, which are opposite to each other in the first direction D1. The third and fourth borders BD3 and BD4 may be extended in the second direction D2.

Gate cutting patterns CT may be disposed in the second direction D2 on a border of each of the first and second single height cells SHC1 and SHC2. For example, the gate cutting patterns CT may be disposed on the third and fourth borders BD3 and BD4 of the first single height cell SHC1. The gate cutting patterns CT may be arranged at the first pitch along the third border BD3. The gate cutting patterns CT may be arranged at the first pitch along the fourth border BD4. When viewed in a plan view, the gate cutting patterns CT on the third and fourth borders BD3 and BD4 may overlap the gate electrodes GE, respectively. The gate cutting patterns CT may be formed of or include at least one of insulating materials (e.g., silicon oxide, silicon nitride, or combinations thereof).

The gate electrode GE on the first single height cell SHC1 may be separated from the gate electrode GE on the second single height cell SHC2 by the gate cutting pattern CT. The gate cutting pattern CT may be interposed between the gate electrodes GE, which are placed on the first and second single height cells SHC1 and SHC2 and are aligned to each other in the first direction D1. That is, the gate electrode GE extending in the first direction D1 may be divided into a plurality of gate electrodes GE by the gate cutting patterns CT.

Referring back to FIGS. 4 and 5A to 5E, a pair of gate spacers GS may be disposed on opposite side surfaces of the outer electrode PO4 of the gate electrode GE, respectively. The gate spacers GS may be extended along the gate electrode GE and in the first direction D1. Top surfaces of the gate spacers GS may be higher than a top surface of the gate electrode GE. The top surfaces of the gate spacers GS may be substantially coplanar with a top surface of a first interlayer insulating layer 110, which will be described below. The gate spacers GS may be formed of or include at least one of SiCN, SiCON, or SiN. In an example embodiment, the gate spacers GS may be a multi-layered structure, which includes at least two different materials selected from SiCN, SiCON, and SiN.

A gate capping pattern GP may be provided on the gate electrode GE. The gate capping pattern GP may be extended along the gate electrode GE or in the first direction D1. The gate capping pattern GP may be formed of or include a material having an etch selectivity with respect to first and second interlayer insulating layers 110 and 120, which will be described below. For example, the gate capping pattern GP may be formed of or include at least one of SiON, SiCN, SiCON, or SiN.

A gate insulating layer GI may be interposed between the gate electrode GE and the first channel pattern CH1 and between the gate electrode GE and the second channel pattern CH2. The gate insulating layer GI may cover the top surface TS, the bottom surface BS, and the side surfaces SW of each of the first to third semiconductor patterns SP1, SP2, and SP3. The gate insulating layer GI may cover a top surface of the device isolation layer ST placed below the gate electrode GE. The gate insulating layer GI may be interposed between the first inner electrode PO1 and the first and second insulating patterns AP1 and AP2.

In an example embodiment, the gate insulating layer GI may include a silicon oxide layer, a silicon oxynitride layer, and/or a high-k dielectric layer. The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In an example embodiment, the gate electrode GE may include a first metal pattern and a second metal pattern on the first metal pattern. The first metal pattern may be provided on the gate insulating layer GI and may be adjacent to the first to third semiconductor patterns SP1, SP2, and SP3. The first metal pattern may include a work-function metal, which can be used to adjust a threshold voltage of the transistor. By adjusting a thickness and composition of the first metal pattern, it may be possible to realize a transistor having a desired threshold voltage. For example, the first to third inner electrodes PO1, PO2, and PO3 of the gate electrode GE may be composed of the first metal pattern including the work-function metal.

The first metal pattern may include a metal nitride layer. For example, the first metal pattern may include a layer that is composed of at least one metallic material, which is selected from the group consisting of titanium (Ti), tantalum (Ta), aluminum (Al), tungsten (W), molybdenum (Mo), and nitrogen (N). In an example embodiment, the first metal pattern may further include carbon (C). The first metal pattern may include a plurality of work function metal layers which are stacked.

The second metal pattern may be formed of or include a metallic material whose resistance is lower than the first metal pattern. For example, the second metal pattern may include at least one metallic material, which is selected from the group consisting of tungsten (W), aluminum (Al), titanium (Ti), and tantalum (Ta). In an example embodiment, the outer electrode PO4 of the gate electrode GE may include the first metal pattern and the second metal pattern on the first metal pattern.

The first interlayer insulating layer 110 may be provided on the substrate 105. The first interlayer insulating layer 110 may cover the gate spacers GS and the first and second source/drain patterns SD1 and SD2. A top surface of the first interlayer insulating layer 110 may be substantially coplanar with a top surface of the gate capping pattern GP and a top surface of the gate spacer GS. A second interlayer insulating layer 120 may be formed on the first interlayer insulating layer 110 to cover the gate capping pattern GP. A third interlayer insulating layer 130 may be provided on the second interlayer insulating layer 120. A fourth interlayer insulating layer 140 may be provided on the third interlayer insulating layer 130. In an example embodiment, each of the first to fourth interlayer insulating layers 110-140 may include a silicon oxide layer.

A pair of division structures DB, which are opposite to each other in the second direction D2, may be provided at both sides of each of the first and second single height cells SHC1 and SHC2. For example, a pair of the division structures DB may be provided on the first and second borders BD1 and BD2 of the first single height cell SHC1, respectively. The division structure DB may be extended in the first direction D1 to be parallel to the gate electrodes GE.

The division structure DB may be provided to penetrate the gate capping pattern GP and the gate electrode GE and may be extended into the first and second active patterns AP1 and AP2. The division structure DB may be provided to penetrate an upper portion of each of the first and second insulating patterns AP1 and AP2. The division structure DB may electrically separate an active region of each of the first and second single height cells SHC1 and SHC2 from an active region of a neighboring cell.

Active contacts AC may be provided to penetrate the first and second interlayer insulating layers 110 and 120 and to be electrically connected to the first and second source/drain patterns SD1 and SD2, respectively. Each of the active contacts AC may be provided to be adjacent to a side of the gate electrode GE. When viewed in a plan view, the active contact AC may be a bar-shaped pattern that is extended in the first direction D1.

The active contact AC may be a self-aligned contact. For example, the active contact AC may be formed by a self-alignment process using the gate capping pattern GP and the gate spacer GS. For example, the active contact AC may cover at least a portion of the side surface of the gate spacer GS. Although not shown, the active contact AC may cover a portion of the top surface of the gate capping pattern GP.

A metal-semiconductor compound layer SC (e.g., a silicide layer) may be respectively interposed between the active contact AC and the first source/drain pattern SD1 and between the active contact AC and the second source/drain pattern SD2. The active contact AC may be electrically connected to the source/drain pattern SD1 or SD2 through the metal-semiconductor compound layer SC. For example, the metal-semiconductor compound layer SC may be formed of or include at least one of titanium silicide, tantalum silicide, tungsten silicide, nickel silicide, or cobalt silicide.

Gate contacts GC may be provided to penetrate the second interlayer insulating layer 120 and the gate capping pattern GP and may be electrically connected to the gate electrodes GE, respectively. When viewed in a plan view, two gate contacts GC on the first single height cell SHC1 may be disposed to overlap the first PMOSFET region PR1. In other words, the two gate contacts GC on the first single height cell SHC1 may be provided on the first active pattern AP1 (e.g., see FIG. 5A). When viewed in a plan view, one gate contact GC on the first single height cell SHC1 may be disposed to overlap the first NMOSFET region NR1. In other words, one gate contact GC on the first single height cell SHC1 may be provided on the second active pattern AP2 (e.g., see FIG. 5B).

The gate contact GC may be freely disposed on the gate electrode GE, without any restrictions on its position. As shown in FIG. 4, the gate contacts GC on the second single height cell SHC2 may be disposed on the second PMOSFET region PR2, the second NMOSFET region NR2, and the device isolation layer ST filling the trench TR, respectively.

An upper portion of the active contact AC adjacent to the gate contact GC may be filled with an upper insulating pattern UIP. A bottom surface of the upper insulating pattern UIP may be lower than a bottom surface of the gate contact GC. In other words, a top surface of the active contact AC adjacent to the gate contact GC may be formed at a level, which is lower than the bottom surface of the gate contact GC, by the upper insulating pattern UIP. Accordingly, by blocking or preventing the gate contact GC and the active contact AC adjacent thereto from contacting each other, a short circuit issue from occurring therebetween may be reduced or prevented. The upper insulating pattern UIP may be formed of or include at least one of silicon-based insulating materials (e.g., silicon oxide, silicon nitride, and silicon oxynitride).

Each of the active and gate contacts AC and GC may include a conductive pattern FM and a barrier pattern BM enclosing the conductive pattern FM. For example, the conductive pattern FM may be formed of or include at least one of metallic materials (e.g., aluminum, copper, tungsten, molybdenum, and cobalt). The barrier pattern BM may cover side and bottom surfaces of the conductive pattern FM. In an example embodiment, the barrier pattern BM may include a metal layer and a metal nitride layer. The metal layer may be formed of or include at least one of titanium, tantalum, tungsten, nickel, cobalt, or platinum. The metal nitride layer may be formed of or include at least one of titanium nitride (TiN), tantalum nitride (TaN), tungsten nitride (WN), nickel nitride (NiN), cobalt nitride (CON), or platinum nitride (PtN).

Referring to FIGS. 4 and 5C to 5E, the first to third lower power lines VPR1, VPR2, and VPR3 may be provided in a lower portion of the substrate 105. The first to third lower power lines VPR1, VPR2, and VPR3 may be extended in the second direction D2 to be parallel to each other. The first lower power line VPR1 may be disposed on the fourth border BD4 of the first single height cell SHC1. The second lower power line VPR2 may be disposed on the third border BD3 of the first single height cell SHC1. In other words, the first single height cell SHC1 may be defined between the first lower power line VPR1 and the second lower power line VPR2. The second single height cell SHC2 may be defined between the second lower power line VPR2 and the third lower power line VPR3.

In an example embodiment, the first lower power line VPR1 may vertically overlap the first NMOSFET region NR1. The second lower power line VPR2 may vertically overlap the first PMOSFET region PR1 and the second PMOSFET region PR2. The third lower power line VPR3 may vertically overlap the second NMOSFET region NR2.

The first to third lower power lines VPR1 to VPR3 may be formed of or include at least one selected from the group consisting of copper, molybdenum, tungsten, and ruthenium. A bottom surface of each of the first to third lower power lines VPR1 to VPR3 may be coplanar with a bottom surface of the substrate 105.

A power delivery network layer PDN may be provided on the bottom surface of the substrate 105. The power delivery network layer PDN may include a plurality of lower interconnection lines, which are electrically connected to the first to third lower power lines VPR1 to VPR3. As an example, the power delivery network layer PDN may include a wiring network, which is used to apply the source voltage VSS to the first and third lower power lines VPR1 and VPR3. The power delivery network layer PDN may include a wiring network, which is used to apply the drain voltage VDD to the second lower power line VPR2.

Referring back to FIGS. 4, 5A, 5B, and 5D, a first back-side contact BSC1 may be provided to vertically extend from the second lower power line VPR2 to the first source/drain pattern SD1 through the substrate 105. A second back-side contact BSC2 may be provided to vertically extend from the first lower power line VPR1 to the second source/drain pattern SD2 through the substrate 105. A width of the first and second back-side contacts BSC1 and BSC2 in the second direction D2 may decrease as a distance from the bottom surface of the substrate 105 increases in the vertical direction D3.

The first back-side contact BSC1 may be a pillar-shaped conductive pattern vertical and electrically connecting the second lower power line VPR2 to the first source/drain pattern SD1. The drain voltage VDD may be applied to the first source/drain pattern SD1 through the first back-side contact BSC1.

The second back-side contact BSC2 may have a conductive pillar shape and may be used to connect the first lower power line VPR1 to the second source/drain pattern SD2 vertically and electrically. The source voltage VSS may be applied to the second source/drain pattern SD2 through the second back-side contact BSC2.

Referring to FIG. 4 and FIGS. 5A to 5E, a first metal layer M1 may be provided in the third interlayer insulating layer 130. The first metal layer M1 may include first interconnection lines M1_I. The first interconnection lines M1_I of the first metal layer M1 may be extended in the second direction D2 to be parallel to each other.

According to an example embodiment of the inventive concepts, a power line, which is used to supply a power to the single height cell SHC, may be provided in the form of the lower power line VPR1-VPR3 and may be buried in the substrate 105. Thus, the power line may be omitted from the first metal layer M1. The first interconnection lines M1_I, which are used for signal transmission, may be disposed in the first metal layer M1.

The first metal layer M1 may further include first vias VI1. The first vias VI1 may be provided below the first interconnection lines M1_I of the first metal layer M1, respectively. The first interconnection line M1_I of the first metal layer M1 may be electrically connected to the active contact AC through the first via VI1. The first interconnection line M1_I of the first metal layer M1 may be electrically connected to the gate contact GC through the first via VI1.

The first interconnection line M1_I of the first metal layer M1 and the first via VI1 thereunder may be separately formed by different processes. That is, each of the first interconnection line M1_I and the first via VI1 of the first metal layer M1 may be formed by a single damascene process. The semiconductor device according to the present example embodiment may be fabricated using a sub-20 nm process.

A second metal layer M2 may be provided in the fourth interlayer insulating layer 140. The second metal layer M2 may include a plurality of second interconnection lines M2_I. Each of the second interconnection lines M2_I of the second metal layer M2 may be a line- or bar-shaped pattern that is extended in the first direction D1. In other words, the second interconnection lines M2_I may be extended in the first direction D1 to be parallel to each other.

The second metal layer M2 may further include second vias VI2, which are provided below the second interconnection lines M2_I, respectively. The first interconnection line M1_I of the first metal layer M1 and the second interconnection line M2_I of the second metal layer M2 may be electrically connected to each other through the second via VI2. As an example, the second interconnection line M2_I of the second metal layer M2 and the second via VI2 thereunder may be formed by a dual damascene process.

The first interconnection line M1_I of the first metal layer M1 and the second interconnection line M2_I of the second metal layer M2 may be formed of or include the same conductive material or different conductive materials. For example, the first interconnection line M1_I of the first metal layer M1 and the second interconnection line M2_I of the second metal layer M2 may be formed of or include at least one of metallic materials (e.g., aluminum, copper, tungsten, molybdenum, ruthenium, and cobalt). Although not shown, a plurality of metal layers (e.g., M3, M4, M5, and so forth) may be additionally stacked on the fourth interlayer insulating layer 140. Each of the stacked metal layers may include interconnection lines, which are used as routing paths between cells.

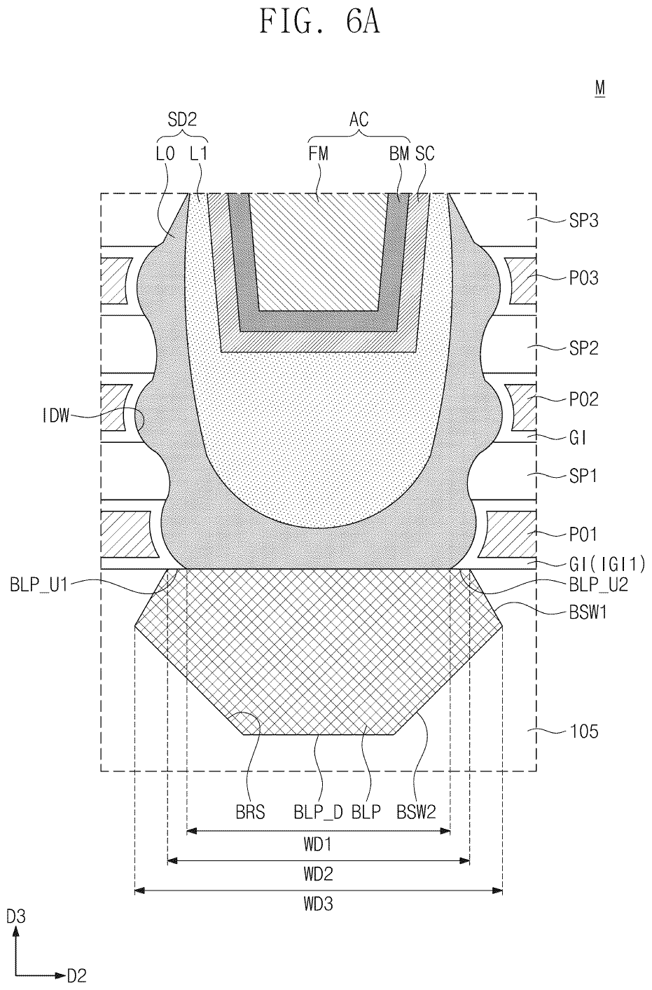

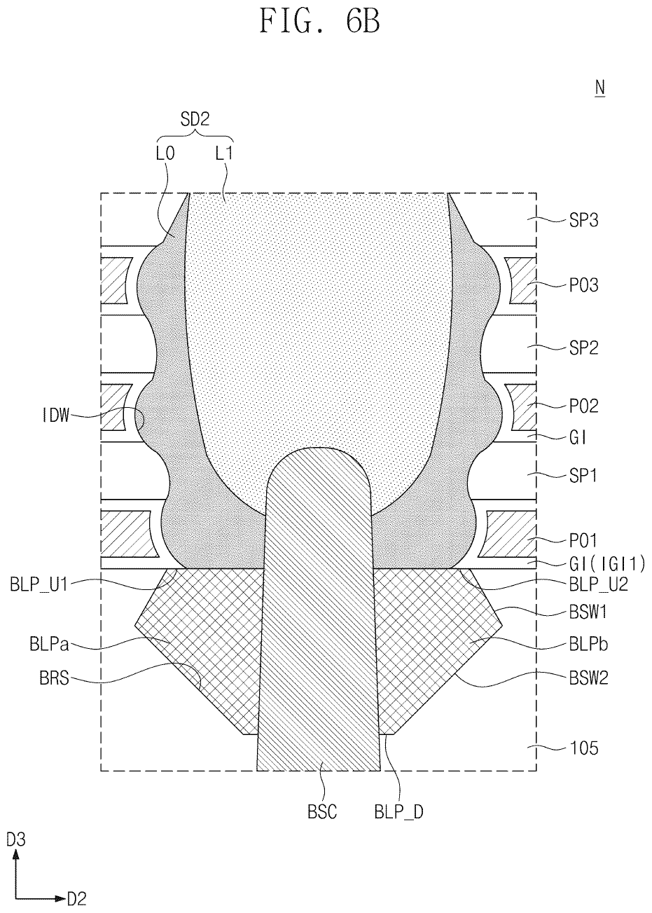

FIG. 6A is an enlarged sectional view illustrating a portion ‘M’ of FIG. 5B. FIG. 6B is an enlarged sectional view illustrating a portion ‘N’ of FIG. 5B. The second source/drain patterns SD2 will be described in more detail with reference to FIGS. 6A and 6B.

Referring to FIGS. 6A and 6B, a blocking pattern BLP may be interposed between the second active pattern AP2 and the second source/drain pattern SD2. The blocking pattern BLP may be provided in a blocking recess BRS, which is formed in an upper portion of the second active pattern AP2. The blocking pattern BLP may be provided under a bottom surface of the second source/drain pattern SD2. A top surface of the blocking pattern BLP may be in direct contact with the bottom surface of the second source/drain pattern SD2.

The bottom surface of the second source/drain pattern SD2 may have a first width WD1 in the second direction D2. The top surface of the blocking pattern BLP may have a second width WD2 in the second direction D2. The second width WD2 may be larger than the first width WD1. A width of the top surface of the blocking pattern BLP may be larger than a width of the bottom surface of the second source/drain pattern SD2.

The blocking pattern BLP may be extended from an edge region of the bottom surface of the second source/drain pattern SD2 in the second direction D2 or an opposite direction D2′ thereof. The blocking pattern BLP may be in direct contact with a first inner gate insulating layer IGI1 covering the first inner electrode PO1. At least a portion of the top surface of the blocking pattern BLP may be in direct contact with a bottom surface of the first inner gate insulating layer IGI1. As an example, the blocking pattern BLP may include a first contact surface BLP_U1 and a second contact surface BLP_U2 that are in contact with the first inner gate insulating layer IGI1. The first and second contact surfaces BLP_U1 and BLP_U2 may be opposite edge regions of the top surface of the blocking pattern BLP.

A side surface of the blocking pattern BLP may include a first surface BSW1 and a second surface BSW2. The first surface BSW1 and the second surface BSW2 may meet each other to define a vertex of the blocking pattern BLP. The first surface BSW1 may have a first slope, and the second surface BSW2 may have a second slope. One of the first and second slopes may be positive, and the other may be negative. For example, the first slope may be negative, and the second slope may be positive.

The largest width of the blocking pattern BLP in the second direction D2 may be a third width WD3. The third width WD3 may be a distance between opposite vertices of the blocking pattern BLP. The third width WD3 may be larger than the first width WD1 and the second width WD2. A width of the blocking pattern BLP in the second direction D2 may increase and then decrease as a distance from a bottom surface BLP_D of the blocking pattern BLP increases in a vertical direction.

The blocking pattern BLP may include a material different from the second source/drain pattern SD2. The blocking pattern BLP may include doped silicon. The blocking pattern BLP may include a material that is chosen to have an etch selectivity with respect to at least one of silicon (Si) or silicon-germanium (SiGe). For example, the blocking pattern BLP may be formed of or include at least one of SiB, SiGeB, SiGeC, or SiC, but the inventive concepts are not limited to this example. In some example embodiments, the blocking pattern BLP may be formed of or include silicon-germanium (SiGe). A germanium concentration of the blocking pattern BLP may range from 0 at % to about 20 at % or from about 40 at % to about 70 at %.

Referring to FIG. 6B, the second back-side contact BSC2 may penetrate the blocking pattern BLP. The second back-side contact BSC2 may be extended into the second source/drain pattern SD2. The blocking pattern BLP may be bisected into a first part BLPa and a second part BLPb by the second back-side contact BSC2. Each of at least a portion BLP_U1 of a top surface of the first part BLPa and at least a portion BLP_U2 of a top surface of the second part BLPb may be in direct contact with the first inner gate insulating layer IGI1. In some example embodiments, an insulating layer may be interposed between the second back-side contact BSC2 and the blocking pattern BLP.

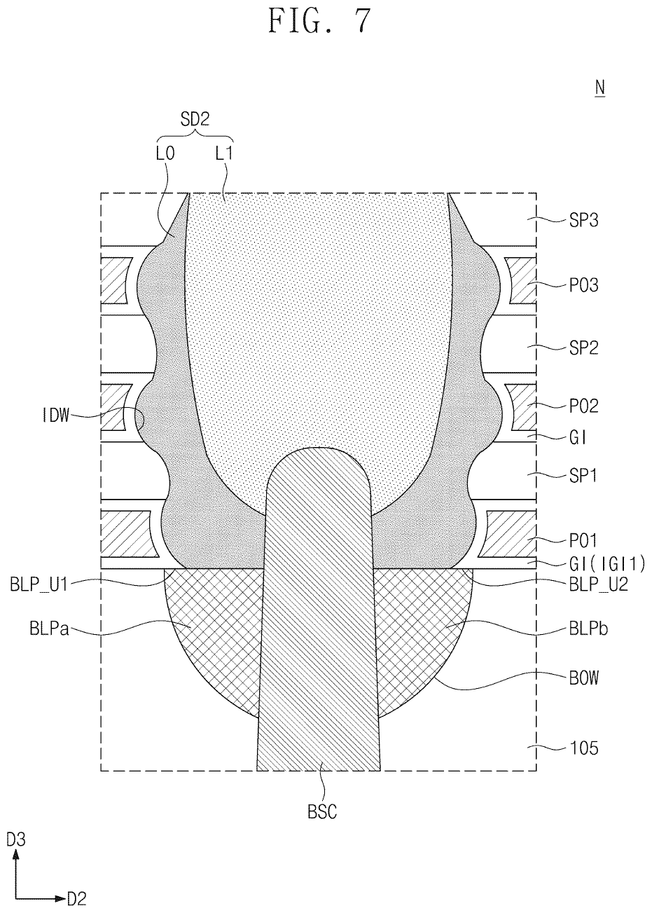

FIG. 7 is an enlarged sectional view illustrating another example of the portion ‘N’ of FIG. 5B. In the following description of the present example embodiment, an element previously described with reference to FIGS. 6A and 6B may be identified by the same reference number without repeating an overlapping description thereof.

Referring to FIG. 7, the blocking pattern BLP may have a semi-oval profile. The blocking pattern BLP may have the largest width at its top level, when measured in the second direction D2. A width of the blocking pattern BLP in the second direction D2 may decrease as a distance from the top surface of the blocking pattern BLP increases in a vertical direction (e.g., in an opposite direction of the third direction D3). An outer side surface BOW of the blocking pattern BLP may be a curved surface. The outer side surface BOW of the blocking pattern BLP may not have any vertex.

The first source/drain pattern SD1 may be substantially the same as the second source/drain pattern SD2 previously described with reference to FIGS. 6A, 6B, and 7. However, the first back-side contact BSC1 may be provided to penetrate the blocking pattern BLP. The blocking pattern BLP may be bisected into a first part and a second part by the first back-side contact BSC1.

In the semiconductor device according to an example embodiment of the inventive concepts, the blocking pattern BLP may be provided between the first active pattern AP1 and the first source/drain pattern SD1 and between the second active pattern AP2 and the second source/drain pattern SD2. A width of the top surface of the blocking pattern BLP may be larger than widths of bottom surfaces of the first and second source/drain patterns SD1 and SD2. Accordingly, the blocking pattern BLP may block or prevent the first and second source/drain patterns SD1 and SD2 from being unintentionally etched or damaged in a process of etching a silicon substrate to be described later. Thus, the reliability and electrical characteristics of the semiconductor device may be improved.

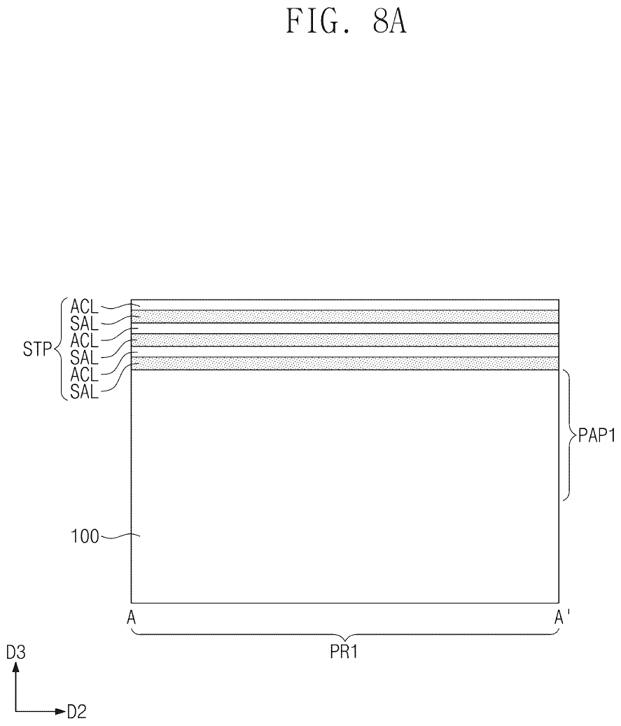

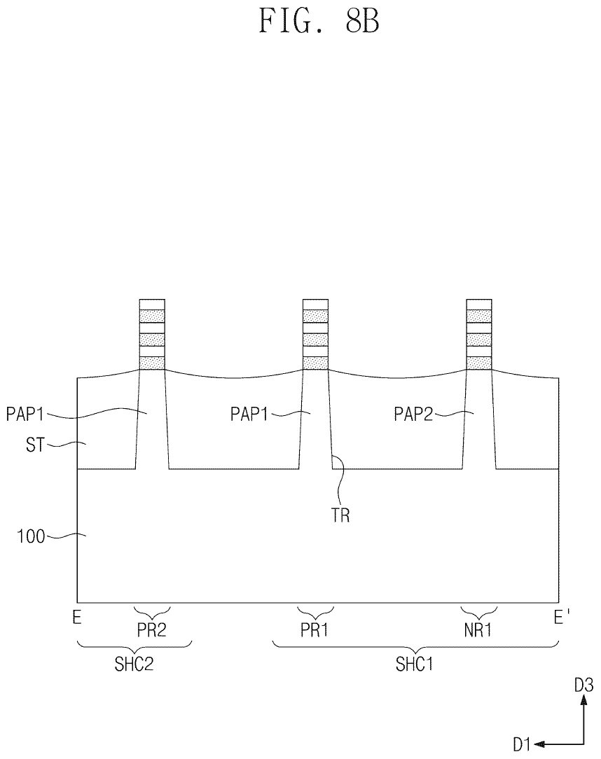

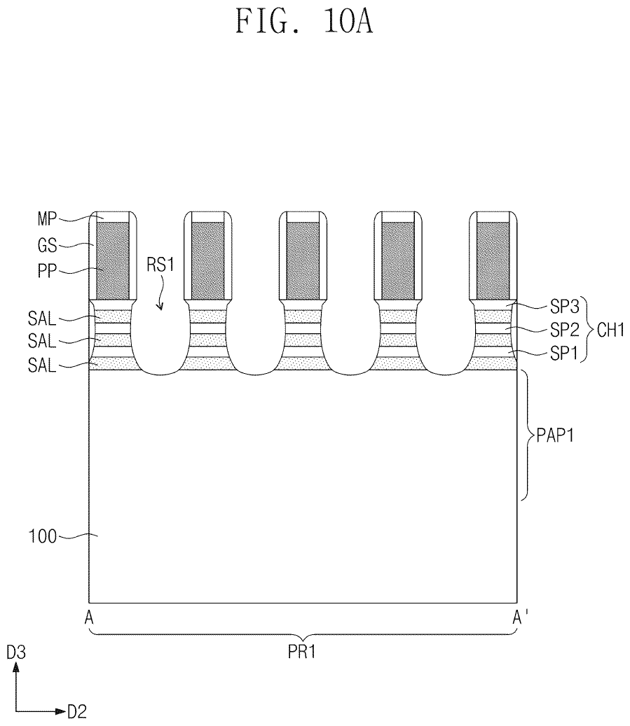

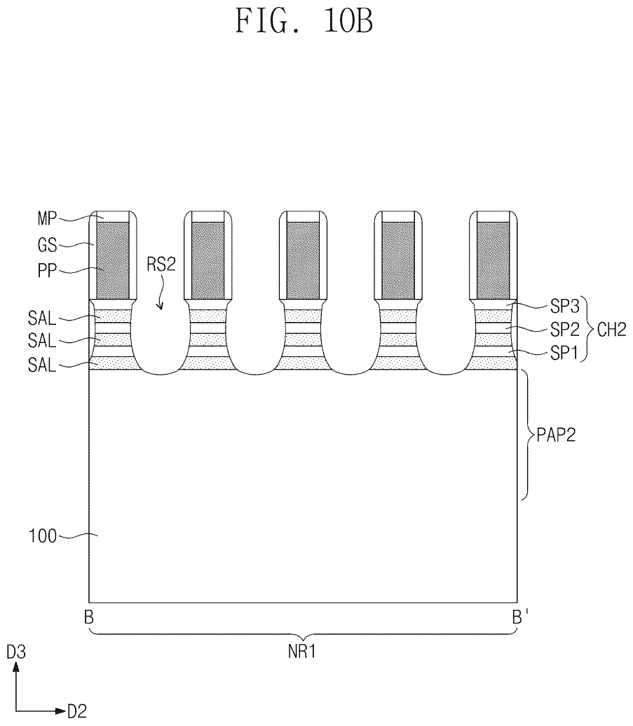

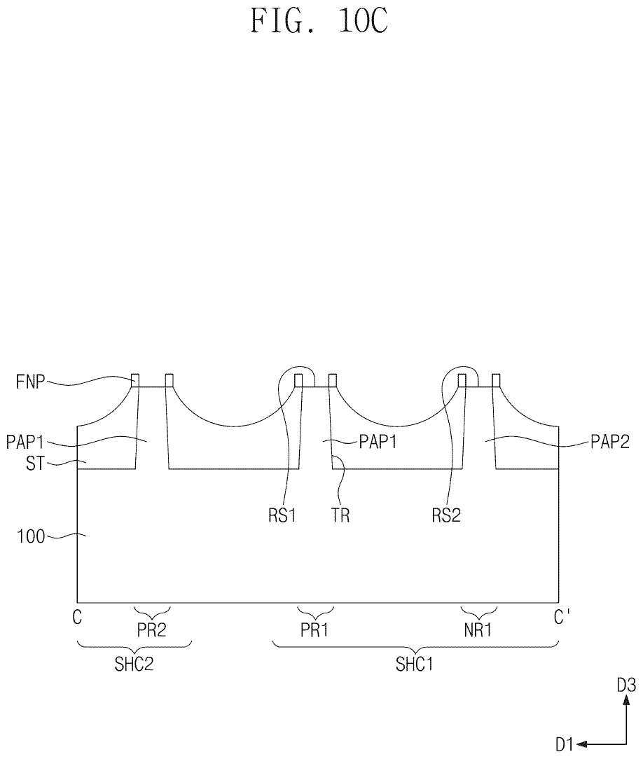

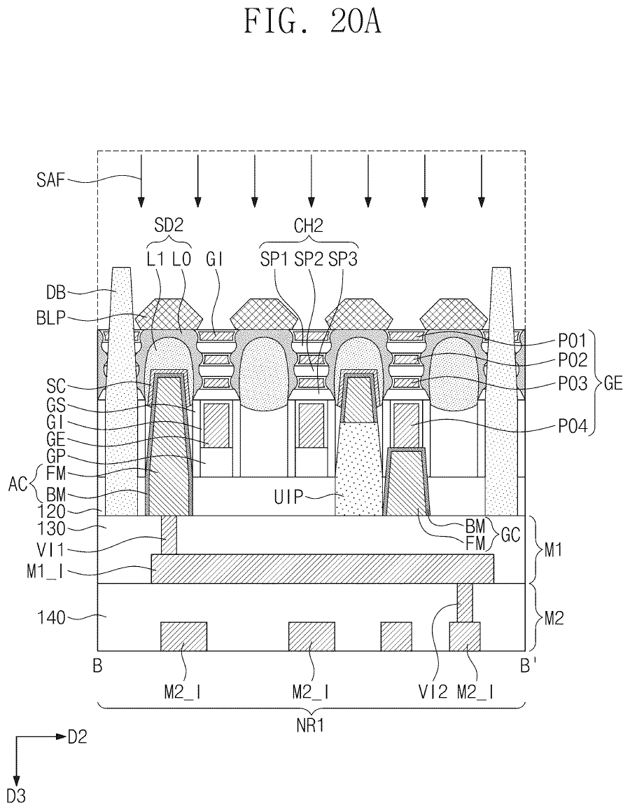

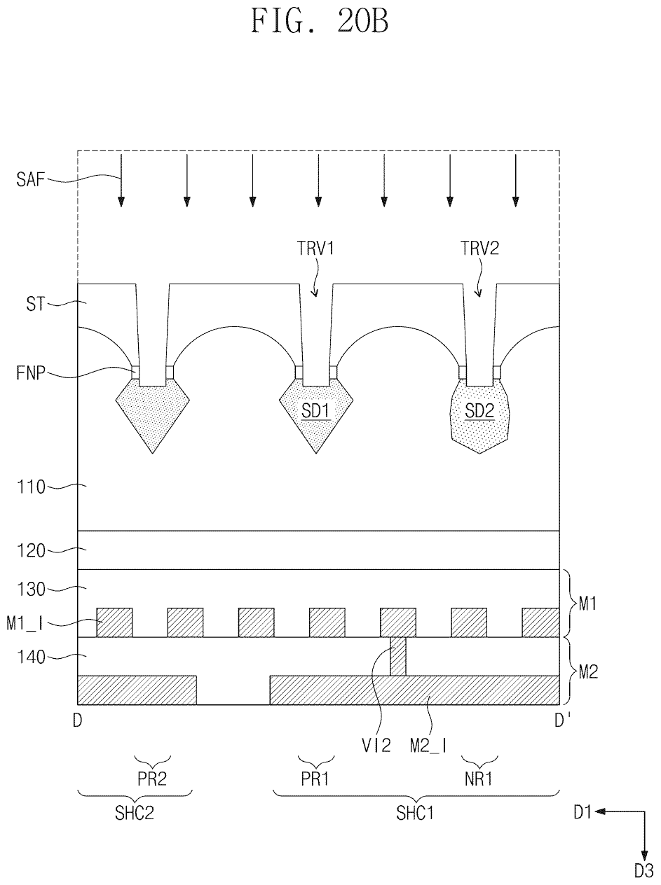

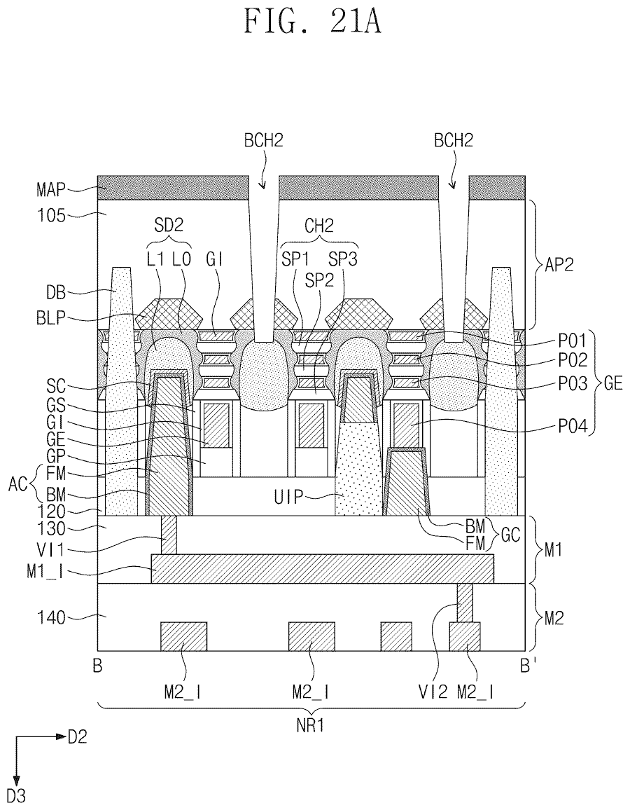

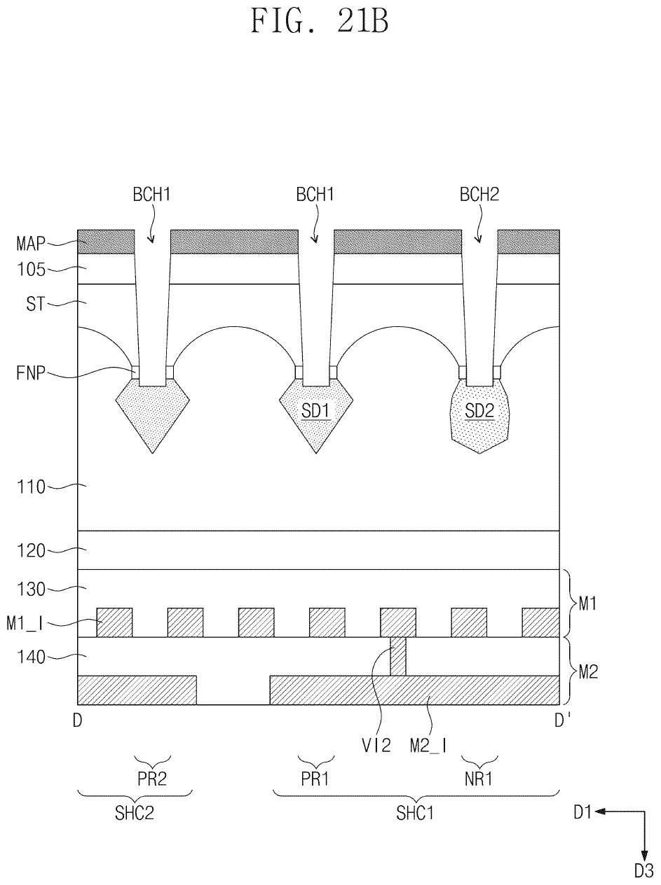

FIGS. 8A to 10C and FIGS. 16A to 21B are sectional views illustrating a method of fabricating a semiconductor device, according to an example embodiment of the inventive concepts. In detail, FIGS. 8A, 9A, 10A, and 19A are sectional views corresponding to the line A-A′ of FIG. 4. FIGS. 10B, 16A, 17A, 18, 19B, 20A, and 21A are sectional views corresponding to the line B-B′ of FIG. 4. FIGS. 10C, 16B, and 19C are sectional views corresponding to the line C-C′ of FIG. 4. FIGS. 20B and 21B are sectional views corresponding to the line D-D′ of FIG. 4. FIGS. 8B, 9B, 17B, and 19D are sectional views corresponding to the line E-E′ of FIG. 4.

Referring to FIGS. 8A and 8B, a semiconductor substrate 100 including the first and second PMOSFET regions PR1 and PR2 and the first and second NMOSFET regions NR1 and NR2 may be provided. In an example embodiment, the semiconductor substrate 100 may be a silicon wafer.

First and second semiconductor layers ACL and SAL, which are alternately stacked on the semiconductor substrate 100, may be formed. Each of the first and second semiconductor layers ACL and SAL may be formed of or include at least one of silicon (Si), germanium (Ge), or silicon-germanium (SiGe), but the first and second semiconductor layers ACL and SAL may be formed of different materials from each other.

The second semiconductor layer SAL may be formed of or include a material that is chosen to have an etch selectivity with respect to the first semiconductor layer ACL. For example, the first semiconductor layers ACL may be formed of or include silicon (Si), and the second semiconductor layers SAL may be formed of or include silicon-germanium (SiGe). Each of the second semiconductor layers SAL may be formed to have a germanium concentration ranging from about 10 at % to about 35 at %.

Mask patterns may be formed on the first and second PMOSFET regions PR1 and PR2 and the first and second NMOSFET regions NR1 and NR2 of the semiconductor substrate 100, respectively. The mask pattern may be a line- or bar-shaped pattern that is extended in the second direction D2.

A patterning process using the mask patterns as an etch mask may be performed to form the trench TR defining a first active pattern PAP1 and a second active pattern PAP2. The first active pattern PAP1 may be formed on each of the first and second PMOSFET regions PR1 and PR2. The second active pattern PAP2 may be formed on each of the first and second NMOSFET regions NR1 and NR2. When viewed in a plan view, the first and second active patterns PAP1 and PAP2 may be line-shaped patterns, which are extended in the second direction D2 to be parallel to each other.

A stacking pattern STP may be formed on each of the first and second active patterns PAP1 and PAP2. The stacking pattern STP may further include the first semiconductor layers ACL and the second semiconductor layers SAL, which are alternately stacked on the first and second active patterns PAP1 and PAP2. The stacking pattern STP may be formed along with the first and second active patterns PAP1 and PAP2, during the patterning process.

The device isolation layer ST may be formed to fill the trench TR. For example, an insulating layer may be formed on a frontside surface of the semiconductor substrate 100 to cover the first and second active patterns PAP1 and PAP2 and the stacking patterns STP. The device isolation layer ST may be formed by recessing the insulating layer until the stacking patterns STP are exposed.

The device isolation layer ST may be formed of or include at least one of insulating materials (e.g., silicon oxide). The stacking patterns STP may be placed at a level higher than the device isolation layer ST and may be exposed to the outside of the device isolation layer ST. In other words, the stacking patterns STP may protrude vertically above the device isolation layer ST.

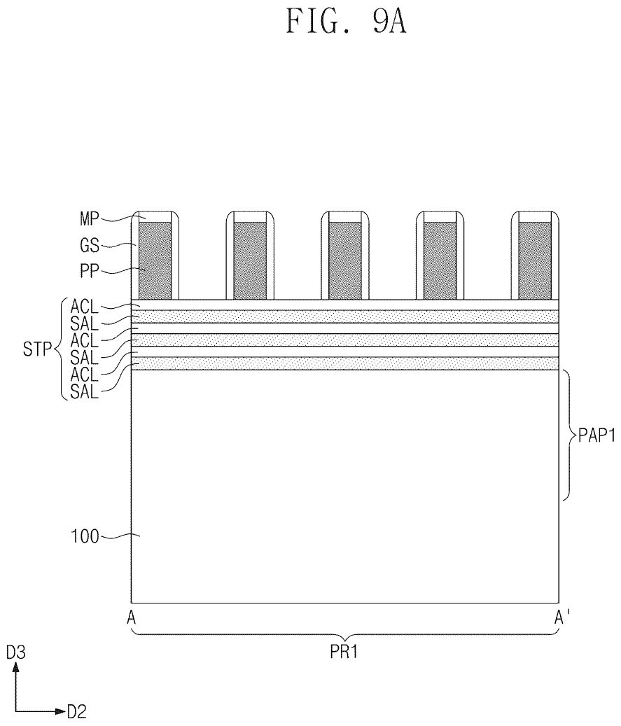

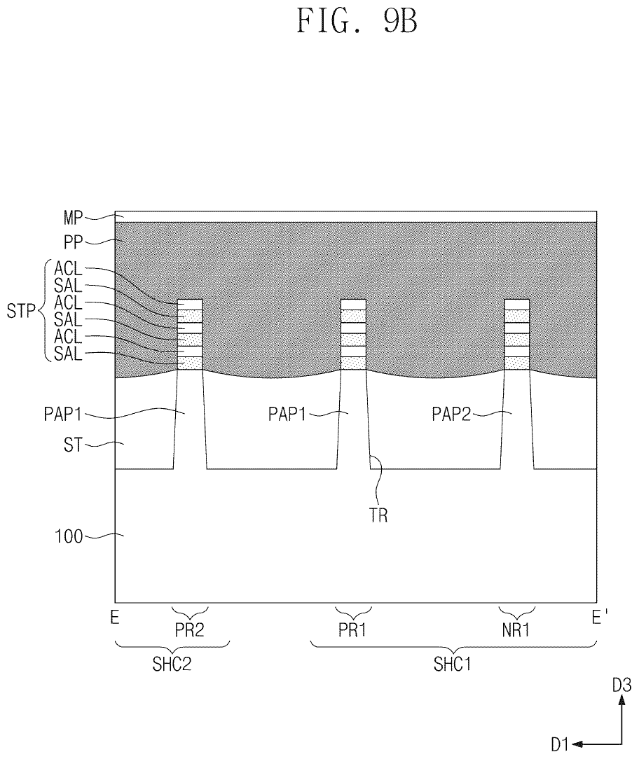

Referring to FIGS. 9A and 9B, sacrificial patterns PP may be formed on the semiconductor substrate 100 to cross the stacking patterns STP. Each of the sacrificial patterns PP may be a line- or bar-shaped pattern that is extended in the first direction D1. The sacrificial patterns PP may be arranged at a first pitch in the second direction D2.

For example, the formation of the sacrificial patterns PP may include forming a sacrificial layer on the semiconductor substrate 100, forming hard mask patterns MP on the sacrificial layer, and patterning the sacrificial layer using the hard mask patterns MP as an etch mask. The sacrificial layer may be formed of or include polysilicon.

A pair of the gate spacers GS may be formed on opposite side surfaces of each of the sacrificial patterns PP. The formation of the gate spacers GS may include conformally forming a gate spacer layer on the semiconductor substrate 100 and anisotropically etching the gate spacer layer. The gate spacer layer may be formed of or include at least one of SiCN, SiCON, or SiN. In an example embodiment, the gate spacer layer may be a multi-layered structure including at least two of SiCN, SiCON, or SiN.

Referring to FIGS. 10A to 10C, first recesses RS1 may be formed in the stacking pattern STP on the first active pattern PAP1. Second recesses RS2 may be formed in the stacking pattern STP on the second active pattern PAP2. The device isolation layer ST at both sides of each of the first and second active patterns PAP1 and PAP2 may be further recessed during the formation of the first and second recesses RS1 and RS2 (e.g., see FIG. 10C).

For example, the first recesses RS1 may be formed by etching the stacking pattern STP on the first active pattern PAP1 using the hard mask patterns MP and the gate spacers GS as an etch mask. The first recess RS1 may be formed between a pair of the sacrificial patterns PP. The second recesses RS2 in the stacking pattern STP on the second active pattern PAP2 may be formed by the same method as that for the first recesses RS1.

Referring back to FIG. 10C, a fence pattern FNP may be formed on each of the first and second active patterns PAP1 and PAP2. The fence pattern FNP may be a remaining portion of the gate spacer GS.

Referring back to FIGS. 10A to 10C, the first to third semiconductor patterns SP1, SP2, and SP3, which are sequentially stacked between adjacent ones of the first recesses RS1, may be formed from the first semiconductor layers ACL, respectively. The first to third semiconductor patterns SP1, SP2, and SP3, which are sequentially stacked between adjacent ones of the second recesses RS2, may be formed from the first semiconductor layers ACL, respectively. The first to third semiconductor patterns SP1, SP2, and SP3 between adjacent ones of the first recesses RS1 may constitute the first channel pattern CH1. The first to third semiconductor patterns SP1, SP2, and SP3 between adjacent ones of the second recesses RS2 may constitute the second channel pattern CH2.

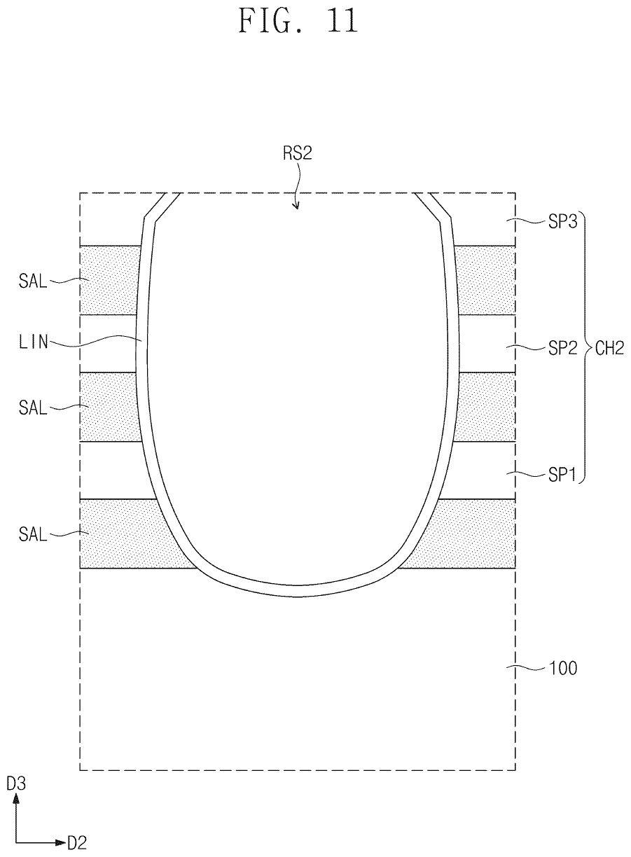

FIGS. 11 to 15 are enlarged views illustrating the portions ‘M’ and ‘N’ of FIG. 5A and illustrating a method of fabricating the semiconductor device of FIGS. 6A and 6B.

Referring to FIG. 11, a liner layer LIN may be conformally formed on inner surfaces of the second recesses RS2. The liner layer LIN may cover side surfaces of first to third semiconductor patterns SP1 to SP3 that are exposed by the second recesses RS2. The liner layer LIN may cover the side surfaces of the second semiconductor layers SAL that are exposed by the second recesses RS2. The liner layer LIN may be formed of or include a silicon-based insulating material (e.g., Si, SiO, SiN, SiOC, or SiOCN). The liner layer LIN may include a material having an etch selectivity with respect to the semiconductor substrate 100.

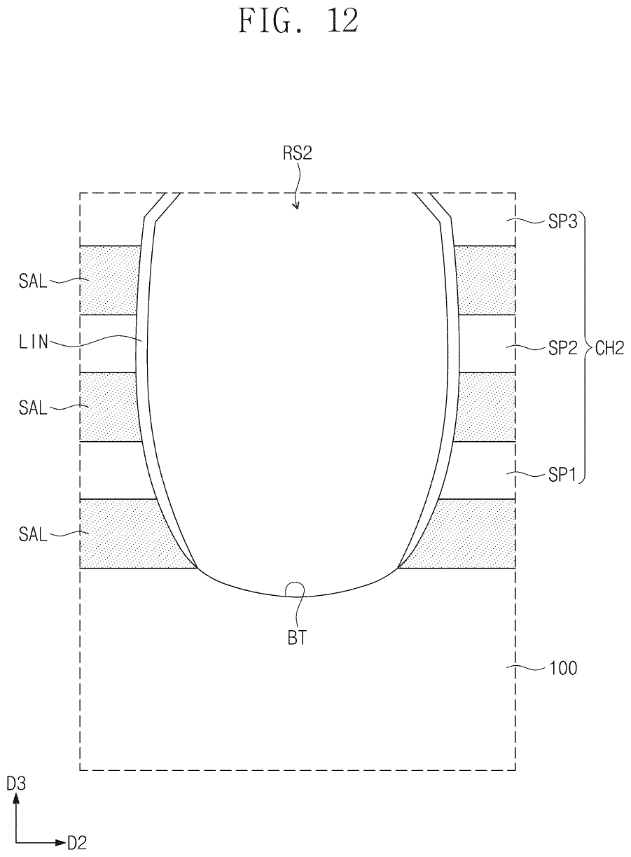

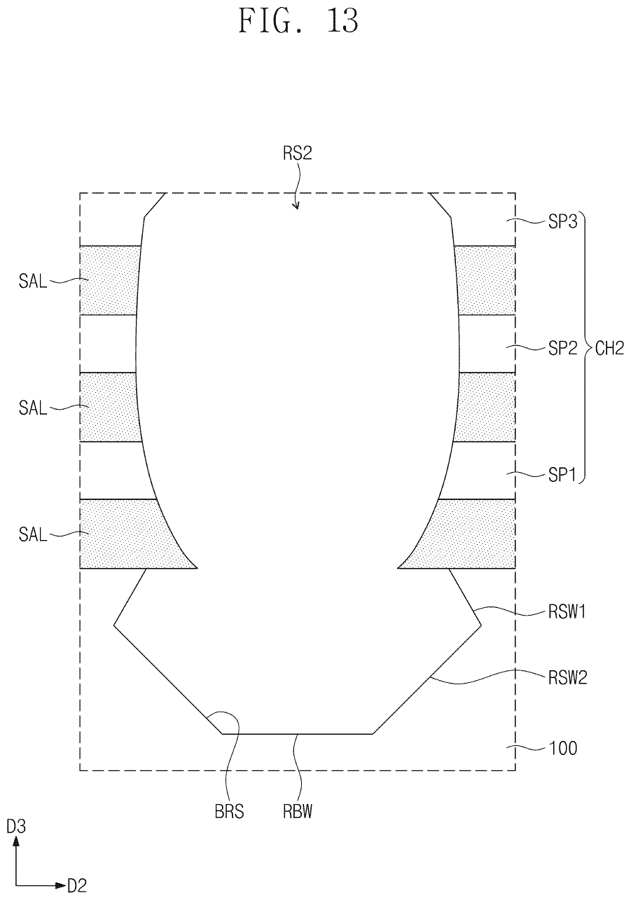

Referring to FIG. 12, an etching process may be performed to remove the liner layer LIN covering a top surface of the semiconductor substrate 100. Because the liner layer LIN is removed, the top surface of the semiconductor substrate 100 may be exposed to the second recesses RS2. The liner layer LIN on the first to third semiconductor patterns SP1 to SP3 and the second semiconductor layers SAL may not be removed. The etching process may be an anisotropic etching process. A thickness of the liner layer LIN may decrease as a distance to the top surface of the semiconductor substrate 100 decreases.

Referring to FIG. 13, an etching process may be performed on the top surface of the semiconductor substrate 100 exposed by the second recesses RS2. The blocking recess BRS may be formed in the semiconductor substrate 100. The liner layer LIN in the second recesses RS2 may be removed.

The etching process may be a dry etching process or a wet etching process. In the case where the etching process is a dry etching process, the blocking recess BRS may have a sharp profile. For example, the blocking recess BRS may have a first inner sidewall RSW1 and a second inner sidewall RSW2. The first inner sidewall RSW1 and the second inner sidewall RSW2 may meet each other. The first inner sidewall RSW1 and the second inner sidewall RSW2 may have slopes that are different from each other. For example, the first inner sidewall RSW1 may have a negative slope, and the second inner sidewall RSW2 may have a positive slope. In the case where the etching process is a wet etching process, the blocking recess BRS may have a rounded profile (e.g., see FIG. 6B).

The first to third semiconductor patterns SP1 to SP3 and the second semiconductor layers SAL may not be etched by the etching process. The smallest width of an upper portion of the blocking recess BRS may be larger than the largest width of a lower portion of the second recesses RS2.

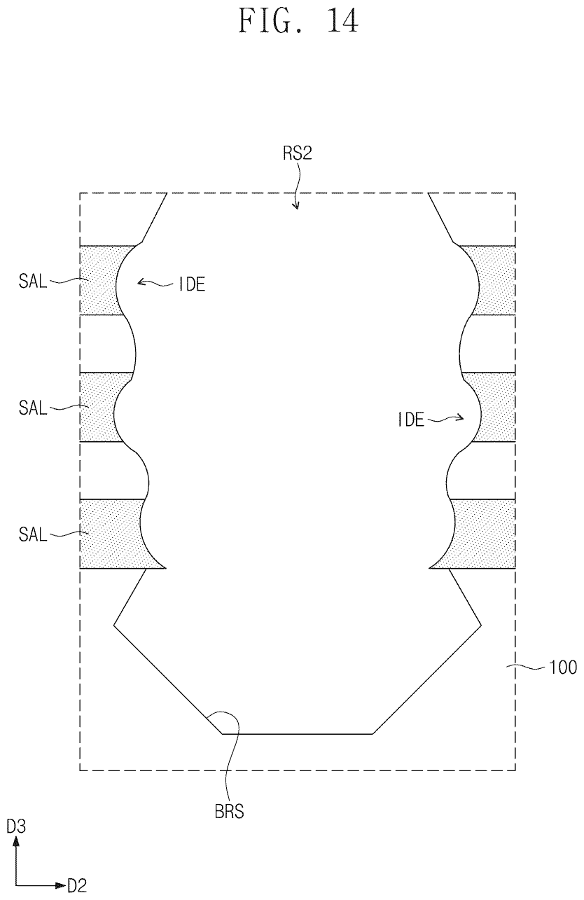

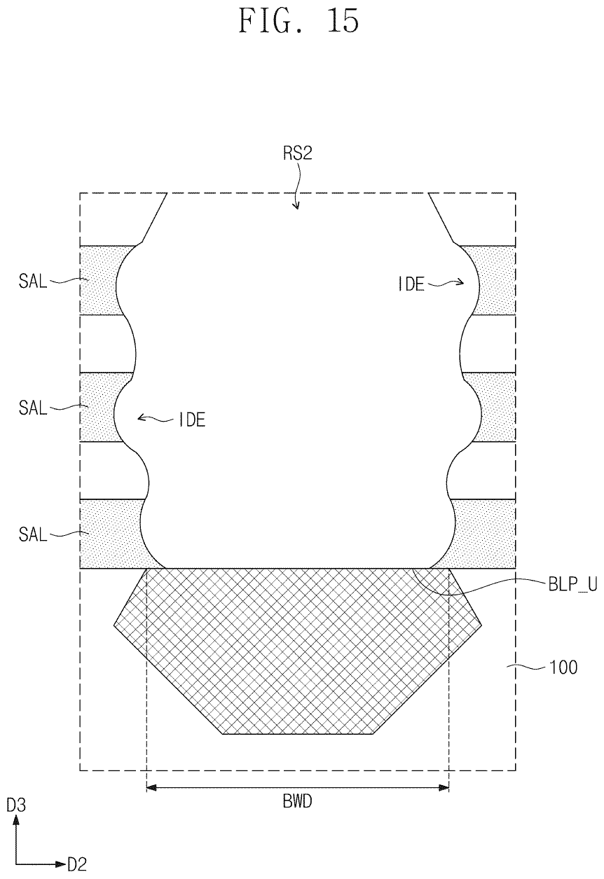

Referring to FIG. 14, the second semiconductor layers SAL may be indented by the etching process to form indent regions IDE. Due to the indent region IDE, the sacrificial layer SAL may have a concave side surface. Owing to the indent region IDE, the side surfaces of the second source/drain patterns SD2 may have a wavy profile. In an example embodiment, an inner spacer may be formed to fill the indent region IDE.

Referring to FIG. 15, the blocking pattern BLP may be formed in the blocking recess BRS. For example, the blocking pattern BLP may be formed by a selective epitaxial growth (SEG) process using an inner surface of the blocking recess BRS as a seed layer. The blocking pattern BLP may be grown using the semiconductor substrate 100, which is exposed by the blocking recess BRS, as a seed layer. In an example embodiment, the SEG process may include a chemical vapor deposition (CVD) process or a molecular beam epitaxy (MBE) process.

In an example embodiment, the blocking pattern BLP may be formed of or include doped silicon. During the formation of the blocking pattern BLP, impurities may be injected into the blocking pattern BLP in an in-situ manner. For example, the blocking pattern BLP may be formed of or include at least one of SiB, SiGeB, SiGeC, or SiC, but the inventive concepts are not limited to this example. In an example embodiment, the blocking pattern BLP may include silicon-germanium (SiGe), and here, a germanium concentration of the blocking pattern BLP may be different from a germanium concentration of the second semiconductor layers SAL. The blocking pattern BLP may include a material having an etch selectivity with respect to the second semiconductor layers SAL.

A top surface BLP_U of the blocking pattern BLP may be in direct contact with the second semiconductor layers SAL. A level of the top surface BLP_U of the blocking pattern BLP may be equal to or higher than a level of a bottom surface of the lowermost one of the second semiconductor layers SAL. A portion of the top surface BLP_U of the blocking pattern BLP may be exposed by the second recesses RS2. A width BWD of the top surface BLP_U of the blocking pattern BLP may be larger than a width of the exposed top surface of the blocking pattern BLP.

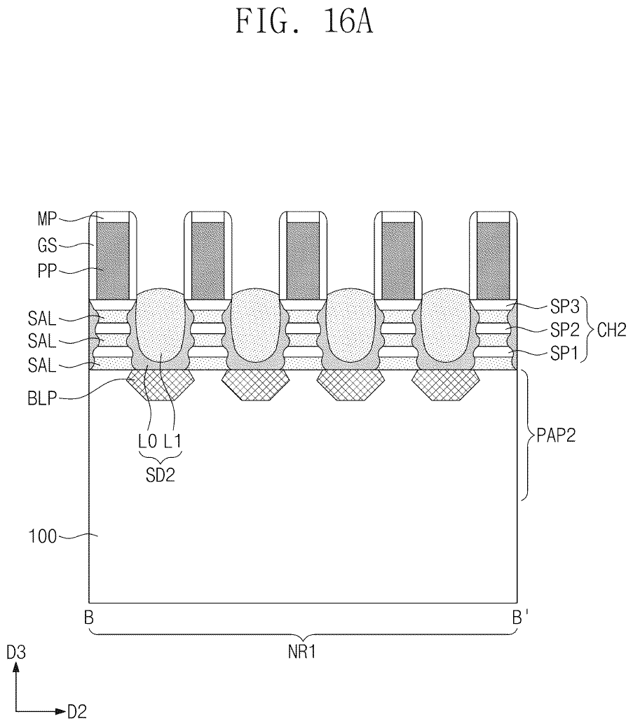

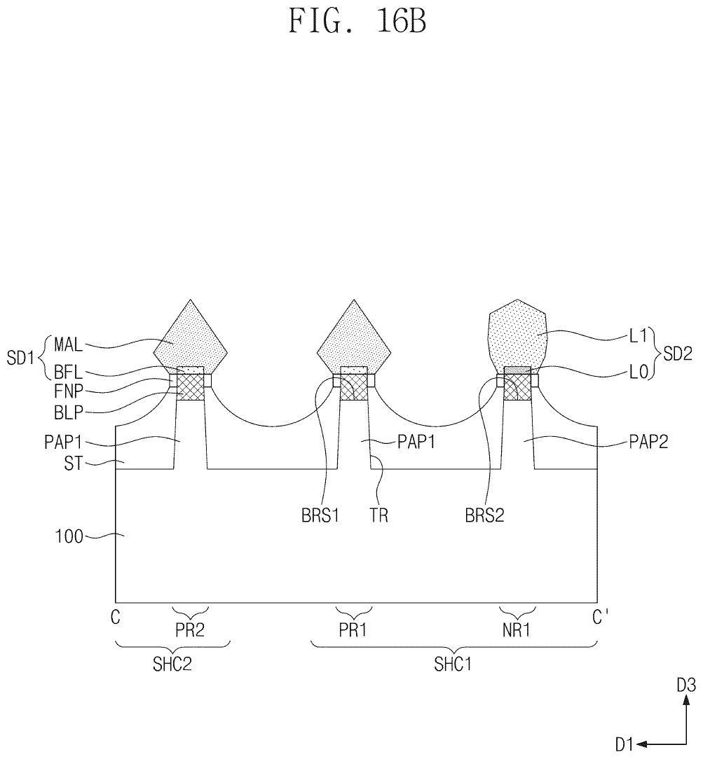

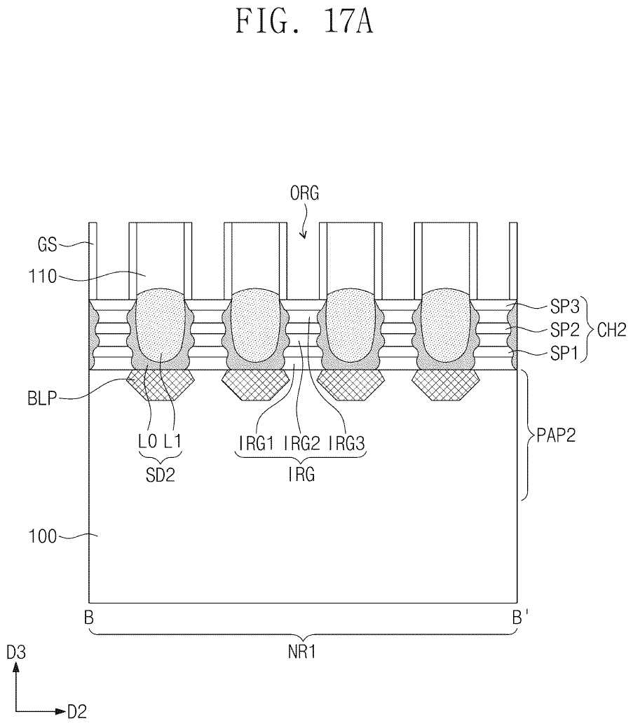

Referring to FIGS. 16A and 16B, the first source/drain patterns SD1 may be formed in the first recesses RS1, respectively. The first source/drain patterns SD1 may be formed on the blocking pattern BLP. For example, the buffer layer BFL may be formed by a first SEG process using an inner surface of the first recess RS1 as a seed layer. The buffer layer BFL may be grown using the first to third semiconductor patterns SP1, SP2, and SP3 and the semiconductor substrate 100, which are exposed through the first recess RS1, as a seed layer. As an example, the first SEG process may include a chemical vapor deposition (CVD) process or a molecular beam epitaxy (MBE) process.

The buffer layer BFL may be formed of or include a semiconductor material (e.g., SiGe) having a lattice constant greater than that of the semiconductor substrate 100. The buffer layer BFL may contain a relatively low concentration of germanium (Ge). In another example embodiment, the buffer layer BFL may contain only silicon (Si), without germanium (Ge). A germanium concentration of the buffer layer BFL may range from 0 at % to about 35 at %.

A second SEG process may be performed on the buffer layer BFL to form the main layer MAL. The main layer MAL may be formed to fill the first recess RS1 completely or nearly completely. The main layer MAL may contain a relatively high concentration of germanium. In an example embodiment, the germanium concentration of the main layer MAL may range from about 30 at % to about 70 at %.

In an example embodiment, a third SEG process may be performed on the main layer MAL to form a capping layer. The capping layer may be formed of or include silicon (Si). A silicon concentration of the capping layer may range from 98 at % to 100 at %.

The first source/drain pattern SD1 may be doped in-situ with p-type impurities (e.g., boron, gallium, or indium) during the formation of the buffer and main layers BFL and MAL. In some example embodiments, the impurities may be injected into the first source/drain pattern SD1, after the formation of the first source/drain pattern SD1.

The second source/drain patterns SD2 may be formed in the second recesses RS2, respectively. The second source/drain patterns SD2 may be formed on the blocking pattern BLP. For example, the second source/drain pattern SD2 may be formed by a SEG process, in which an inner surface of the second recess RS2 is used as a seed layer. In an example embodiment, the second source/drain pattern SD2 may include the same semiconductor material (e.g., Si) as the semiconductor substrate 100.

During the formation of the second source/drain pattern SD2, the second source/drain pattern SD2 may be doped in-situ with n-type impurities (e.g., phosphorus, arsenic, or antimony). In some example embodiments, impurities may be injected into the second source/drain pattern SD2, after the formation of the second source/drain pattern SD2.

In an example embodiment, an inner spacer may be formed by replacing a portion of the second semiconductor layer SAL, which is exposed by the second recess RS2, with an insulating material, before the formation of the second source/drain pattern SD2. Thus, the inner spacers may be formed between the second source/drain pattern SD2 and the second semiconductor layers SAL, respectively.

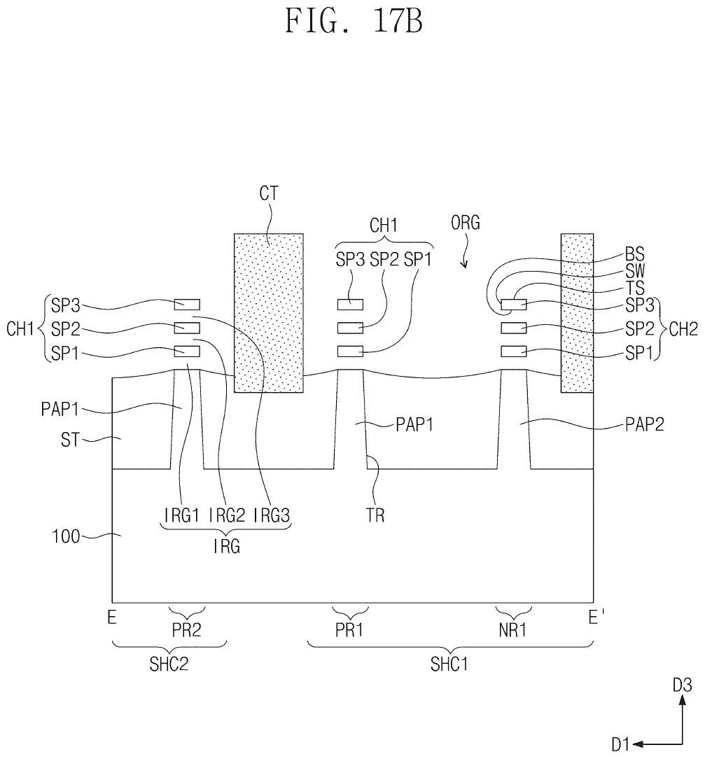

Referring to FIGS. 17A and 17B, the first interlayer insulating layer 110 may be formed to cover the first and second source/drain patterns SD1 and SD2, the hard mask patterns MP, and the gate spacers GS. In an example embodiment, the first interlayer insulating layer 110 may include a silicon oxide layer.

The first interlayer insulating layer 110 may be planarized to expose the top surfaces of the sacrificial patterns PP. The planarization of the first interlayer insulating layer 110 may be performed using an etch-back or chemical-mechanical polishing (CMP) process. All the hard mask patterns MP may be removed during the planarization process. Thus, the first interlayer insulating layer 110 may be formed to have a top surface that is coplanar with the top surfaces of the sacrificial patterns PP and the top surfaces of the gate spacers GS.

A photolithography process may be performed to selectively open a region of the sacrificial pattern PP. For example, a region of the sacrificial pattern PP on the third and fourth borders BD3 and BD4 of the first single height cell SHC1 may be selectively opened. The opened region of the sacrificial pattern PP may be selectively etched and removed. The gate cutting pattern CT may be formed by filling a space, which is formed by removing the sacrificial pattern PP, with an insulating material (e.g., see FIG. 17B).

In an example embodiment, the exposed sacrificial patterns PP may be selectively removed. As a result of the removal of the sacrificial pattern PP, an outer region ORG exposing the first and second channel patterns CH1 and CH2 may be formed. The removal of the sacrificial patterns PP may include a wet etching process which is performed using an etching solution capable of selectively etching polysilicon.

The second semiconductor layers SAL exposed through the outer region ORG may be selectively removed to form inner regions IRG. For example, an etching process of selectively etching the second semiconductor layers SAL may be performed to leave the first to third semiconductor patterns SP1, SP2, and SP3 and to remove only the second semiconductor layers SAL. An etch recipe for the etching process may be chosen to etch a layer (e.g., a silicon germanium layer), which has a relatively high germanium concentration, at a high etch rate. For example, the etching process may be chosen to have a high etch rate to a silicon germanium layer whose germanium concentration is higher than about 10 at %.

During the etching process, the second semiconductor layers SAL may be completely removed from the first and second PMOSFET regions PR1 and PR2 and the first and second NMOSFET regions NR1 and NR2. The etching process may be a wet etching process. An etchant material, which is used in the etching process, may be chosen to quickly remove the second semiconductor layer SAL having a relatively high germanium concentration. Meanwhile, the first source/drain patterns SD1 on the first and second PMOSFET regions PR1 and PR2 may be protected from the etching process by the buffer layer BFL having a relatively low germanium concentration.

The blocking pattern BLP may remain un-etched during the etching process. The blocking pattern BLP may include a material having an etch selectivity with respect to the second semiconductor layers SAL.

Because the second semiconductor layers SAL are selectively removed, only the stacked first to third semiconductor patterns SP1, SP2, and SP3 may be left on each of the first and second active patterns PAP1 and PAP2. Empty regions, which are formed by removing the second semiconductor layers SAL, may be used as first to third inner regions IRG1, IRG2, and IRG3, respectively. For example, the first inner region IRG1 may be formed between the first and second active patterns PAP1 and PAP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

At least a portion of the top surface of the blocking pattern BLP may be exposed to the first inner region IRG1. For example, an edge region of the top surface of the blocking pattern BLP may be exposed to the first inner region IRG1.

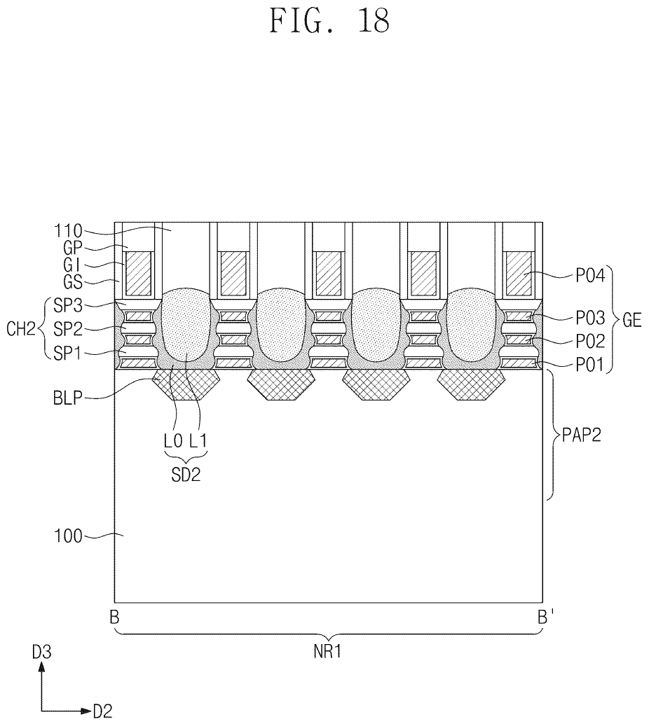

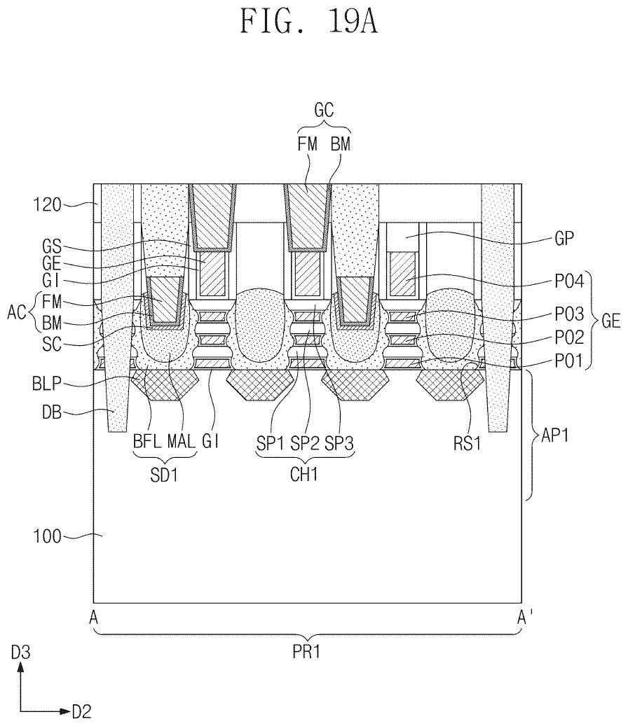

Referring to FIG. 18, the gate insulating layer GI may be conformally formed on the exposed first to third semiconductor patterns SP1, SP2, and SP3. Referring back to FIGS. 6A and 6B, the gate insulating layer GI formed in the first inner region IRG1 may be the first inner gate insulating layer IGI1. The first inner gate insulating layer IGI1 may cover a top surface of the blocking pattern BLP exposed by the first inner region IRG1.

The gate electrode GE may be formed on the gate insulating layer GI. The gate electrode GE may include the first to third inner electrodes PO1, PO2, and PO3, which are formed in the first to third inner regions IRG1, IRG2, and IRG3, respectively, and the outer electrode PO4, which is formed in the outer region ORG.

The gate electrode GE may be vertically recessed to have a reduced height. Upper portions of gate cutting patterns CT may be slightly recessed, during the recessing of the gate electrode GE. The gate capping pattern GP may be formed on the recessed gate electrode GE.

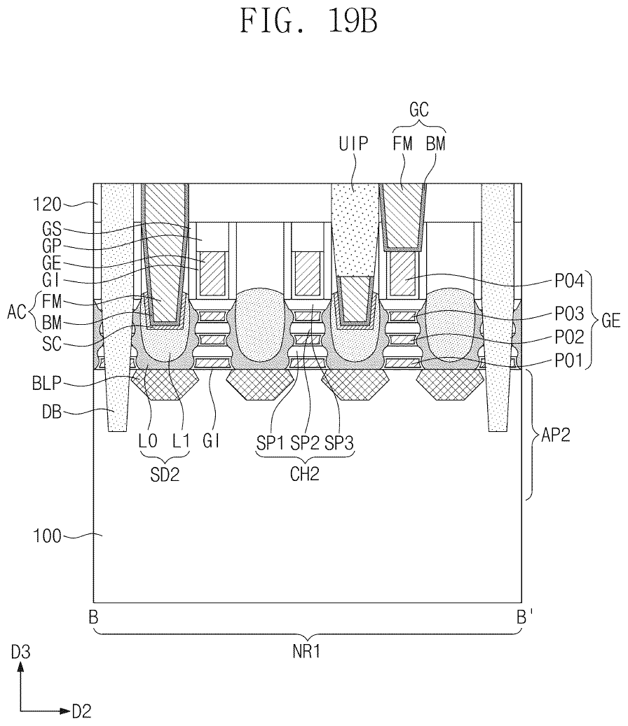

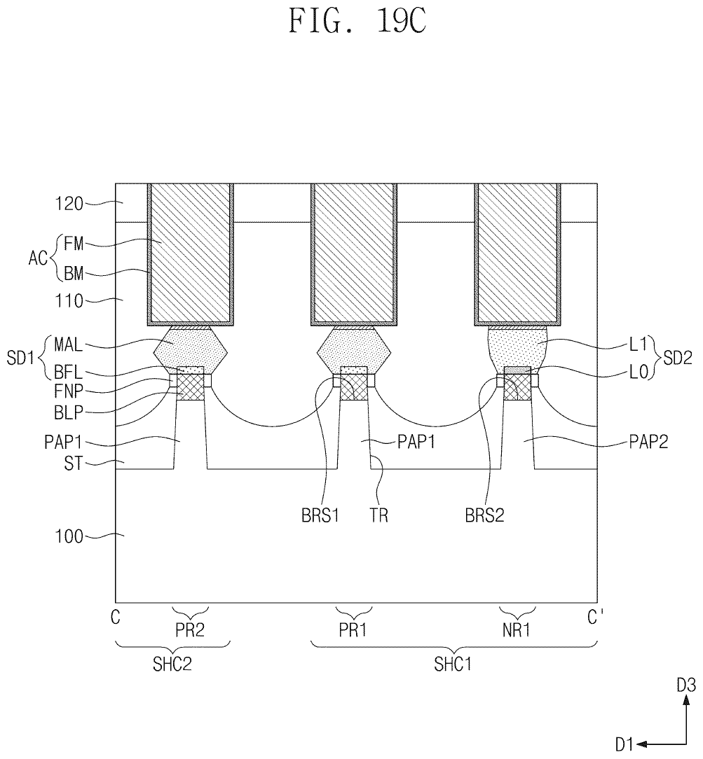

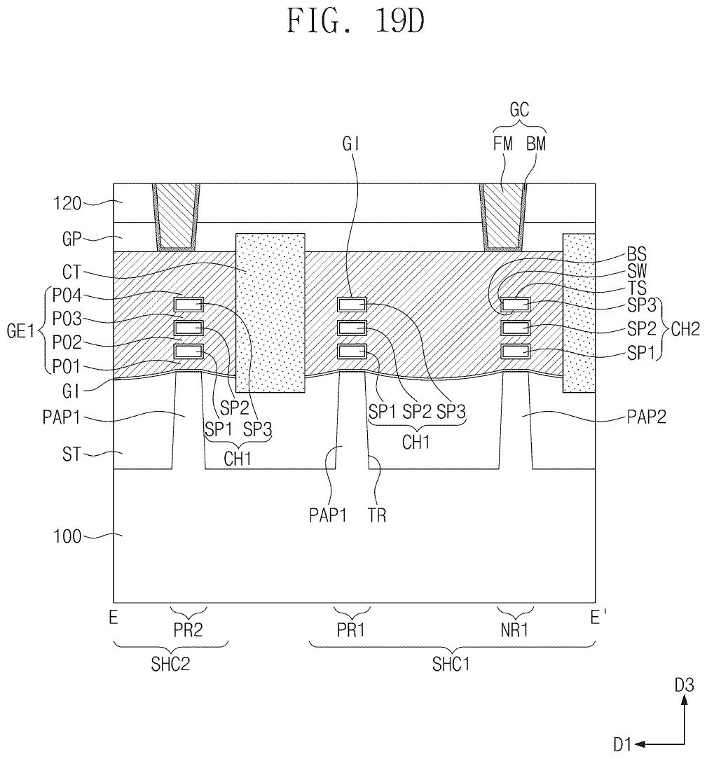

Referring to FIGS. 19A to 19D, the second interlayer insulating layer 120 may be formed on the first interlayer insulating layer 110. The second interlayer insulating layer 120 may include a silicon oxide layer. The active contact AC may be formed to penetrate the second interlayer insulating layer 120 and the first interlayer insulating layer 110 and to be electrically connected to at least one of the first and second source/drain patterns SD1 and SD2. The gate contact GC may be formed to penetrate the second interlayer insulating layer 120 and the gate capping pattern GP and to be electrically connected to the gate electrode GE.

The formation of the active and gate contacts AC and GC may include forming the barrier pattern BM and forming the conductive pattern FM on the barrier pattern BM. The barrier pattern BM may be conformally formed and may include a metal layer and a metal nitride layer. The conductive pattern FM may be formed of or include a low resistance metallic material.

Referring back to FIG. 4 and FIGS. 5A to 5E, the third interlayer insulating layer 130 may be formed on the active contacts AC and the gate contacts GC. The first metal layer M1 may be formed in the third interlayer insulating layer 130. The first metal layer M1 may include the first interconnection line M1_I, which is electrically connected to at least one of the active and gate contacts AC and GC. The fourth interlayer insulating layer 140 may be formed on the third interlayer insulating layer 130. The second metal layer M2 may be formed in the fourth interlayer insulating layer 140.

Referring to FIGS. 20A and 20B, if a BEOL process is finished, the semiconductor substrate 100 may be inverted such that a bottom surface of the semiconductor substrate 100 is exposed to the outside. The exposed semiconductor substrate 100 may be fully removed.

In an example embodiment, the removal of the semiconductor substrate 100 may include performing a planarization process SAF on the bottom surface of the semiconductor substrate 100 to reduce a thickness of the semiconductor substrate 100 and performing a cleaning process to selectively remove a silicon residue from the semiconductor substrate 100.

The blocking pattern BLP may not be removed during the planarization process SAF or the cleaning process. This is because the blocking pattern BLP includes a material having an etch selectivity with respect to the semiconductor substrate 100. Because the bottom surfaces of the first and second source/drain patterns SD1 and SD2 are fully covered with the top surface of the blocking pattern BLP, the blocking pattern BLP may protect the first and second source/drain patterns SD1 and SD2 from a process of removing the semiconductor substrate 100. Accordingly, it may be possible to block or prevent the first and second source/drain patterns SD1 and SD2 from being unintentionally etched or damaged.

As a result of the removal of the semiconductor substrate 100, a first back-side trench TRV1 may be formed in a region occupied by the first active pattern PAP1. As a result of the removal of the semiconductor substrate 100, a second back-side trench TRV2 may be formed in a region occupied by the second active pattern PAP2 (e.g., see FIG. 20B).

Referring to FIGS. 21A and 21B, the substrate 105 may be formed by filling an empty region, which is formed by removing the semiconductor substrate 100, with an insulating material. The substrate 105 may include a silicon-based insulating layer. The substrate 105 may include the first active pattern AP1 filling the first back-side trench TRV1. The substrate 105 may include the second active pattern AP2 filling the second back-side trench TRV2.

A mask pattern MAP may be formed on the substrate 105. The mask pattern MAP may be formed through a photolithography process. An anisotropic etching process using the mask pattern MAP as an etch mask may be performed on the substrate 105 to form first and second back-side contact holes BCH1 and BCH2. The first back-side contact hole BCH1 may be formed to expose the first source/drain pattern SD1. The second back-side contact hole BCH2 may be formed to expose the second source/drain pattern SD2. The first and second back-side contact holes BCH1 and BCH2 may penetrate the blocking pattern BLP. The blocking pattern BLP may be bisected by the first and second back-side contact holes BCH1 and BCH2.

Referring back to FIGS. 5A to 5E, the mask pattern MAP may be selectively removed. The first and second back-side contacts BSC1 and BSC2 may be formed by filling the first and second back-side contact holes BCH1 and BCH2 with a metallic material.

The lower power lines VPR1-VPR3 may be formed on the substrate 105. The lower power line VPR1, VPR2, or VPR3 may be connected to at least one of the first and second back-side contacts BSC1 and BSC2. The power delivery network layer PDN may be formed on the lower power lines VPR1-VPR3. The power delivery network layer PDN may be formed to apply a source or drain voltage to the lower power lines VPR1 to VPR3.

According to an example embodiment of the inventive concepts, a blocking pattern may be provided on a bottom surface of a source/drain pattern. The bottom surface of the source/drain pattern may be fully covered with a top surface of the blocking pattern. In addition, the top surface of the blocking pattern may be in direct contact with a portion of a gate insulating layer. Accordingly, the blocking pattern may block or prevent the source/drain pattern from being unintentionally etched or damaged by a process of etching a silicon substrate. Thus, the reliability and electrical characteristics of the semiconductor device may be improved.

While some example embodiments of the inventive concepts have been particularly shown and described, it will be understood by one of ordinary skill in the art that variations in form and detail may be made therein without departing from the spirit and scope of the attached claims.

What is claimed is:

1. A semiconductor device, comprising:
a substrate including an active pattern;
a source/drain pattern on the substrate; and
a blocking pattern between the active pattern and the source/drain pattern,
wherein a top surface of the blocking pattern is in contact with a bottom surface of the source/drain pattern,
the bottom surface of the source/drain pattern has a first width in a first direction,
the top surface of the blocking pattern has a second width in the first direction, and
the second width is larger than the first width.

2. The semiconductor device of claim 1, wherein the blocking pattern is extended from an edge of the bottom surface of the source/drain pattern in the first direction or an opposite direction thereof.

3. The semiconductor device of claim 1, further comprising:
a lower power line buried in a lower portion of the substrate; and
a back-side contact penetrating the substrate and electrically connecting the lower power line to the source/drain pattern,
wherein the back-side contact penetrates the blocking pattern.

4. The semiconductor device of claim 3, wherein
the substrate is an insulating substrate,
the semiconductor device further comprises a power delivery network layer below the substrate, and
the power delivery network layer is configured to apply a source or drain voltage to the lower power line.

5. The semiconductor device of claim 1, wherein the blocking pattern includes a material different from the source/drain pattern.

6. The semiconductor device of claim 1, further comprising:
a channel pattern on the active pattern, the channel pattern comprising a plurality of semiconductor patterns, the semiconductor patterns being stacked to be spaced apart from each other, the semiconductor patterns comprising a first semiconductor pattern and a second semiconductor pattern, the first semiconductor pattern being a lowermost one of the semiconductor patterns, the second semiconductor pattern being adjacent to the first semiconductor pattern;
a gate electrode on the semiconductor patterns, the gate electrode comprising an inner gate electrode interposed between the first and second semiconductor patterns; and
an inner gate insulating layer interposed between the inner gate electrode and the source/drain pattern,
wherein an edge of a top surface of the blocking pattern is in direct contact with the inner gate insulating layer.

7. The semiconductor device of claim 1, wherein
the blocking pattern has a semi-oval profile, and
a width of the blocking pattern in the first direction decreases as a downward distance from the top surface of the blocking pattern increases in a vertical direction.

8. The semiconductor device of claim 1, wherein the blocking pattern comprises a material having an etch selectivity with respect to at least one of silicon or silicon-germanium.

9. The semiconductor device of claim 1, wherein a width of the top surface of the blocking pattern is larger than a width of the bottom surface of the source/drain pattern.

10. A semiconductor device, comprising:
a substrate including an active pattern;
a channel pattern on the active pattern, the channel pattern comprising a plurality of semiconductor patterns, the semiconductor patterns stacked to be spaced apart from each other, the semiconductor patterns comprising a first semiconductor pattern and a second semiconductor pattern, the first semiconductor pattern being a lowermost one of the semiconductor patterns, the second semiconductor pattern being adjacent to the first semiconductor pattern;
a lower power line buried in a lower portion of the substrate;
a source/drain pattern on the substrate;
a gate electrode on the semiconductor patterns, the gate electrode comprising a first inner gate electrode between the first semiconductor pattern and the second semiconductor pattern;
a first inner gate insulating layer interposed between the first inner gate electrode and the source/drain pattern; and
a blocking pattern between the active pattern and the source/drain pattern,
wherein at least a portion of a top surface of the blocking pattern is in direct contact with the first inner gate insulating layer.

11. The semiconductor device of claim 10, wherein the blocking pattern contains an impurity different from that in the source/drain pattern.

12. The semiconductor device of claim 10, further comprising:
a back-side contact penetrating the substrate and electrically connecting the lower power line to the source/drain pattern,
wherein the back-side contact penetrates the blocking pattern such that the blocking pattern is bisected into a first part and a second part.

13. The semiconductor device of claim 10, wherein the blocking pattern comprises a material having an etch selectivity with respect to at least one of silicon or silicon-germanium.

14. The semiconductor device of claim 10, wherein
the substrate is an insulating substrate,
the semiconductor device further comprises a power delivery network layer below the substrate, and
the power delivery network layer is configured to apply a source or drain voltage to the lower power line.

15. The semiconductor device of claim 10, wherein a smallest width of the top surface of the blocking pattern is larger than a largest width of a bottom surface of the source/drain pattern.

16. A semiconductor device, comprising:
an insulating substrate;
a channel pattern on the insulating substrate, the channel pattern comprising a plurality of semiconductor patterns, the semiconductor patterns stacked to be spaced apart from each other;
a source/drain pattern connected to the channel pattern;
a gate electrode on the channel pattern;
a gate insulating layer interposed between the gate electrode and the channel pattern;
a gate spacer on a side surface of the gate electrode;
a gate capping pattern on a top surface of the gate electrode;
an interlayer insulating layer covering the source/drain pattern and the gate capping pattern;
a gate contact penetrating the interlayer insulating layer and the gate capping pattern, the gate contact electrically connected to the gate electrode;
a first metal layer on the interlayer insulating layer, the first metal layer comprising a first interconnection line electrically connected to the gate contact;
a lower power line in a lower portion of the insulating substrate;
a back-side contact penetrating the insulating substrate and electrically connecting the lower power line to the source/drain pattern; and
a blocking pattern between the insulating substrate and the source/drain pattern,
wherein a top surface of the blocking pattern is in contact with a bottom surface of the source/drain pattern, and
a width of the top surface of the blocking pattern is larger than a width of the bottom surface of the source/drain pattern.

17. The semiconductor device of claim 16, wherein the blocking pattern comprises a material having an etch selectivity with respect to at least one of silicon or silicon-germanium.

18. The semiconductor device of claim 16, wherein the back-side contact penetrates the blocking pattern such that the blocking pattern is bisected into a first part and a second part by the back-side contact.

19. The semiconductor device of claim 18, wherein
the semiconductor patterns includes a first semiconductor pattern and a second semiconductor pattern, the first semiconductor pattern and the second semiconductor pattern being adjacent to each other,
the gate electrode comprises an inner gate electrode between the first semiconductor pattern and the second semiconductor pattern,
the gate insulating layer comprises an inner gate insulating layer interposed between the inner gate electrode and the source/drain pattern, and
the first part and the second part are in direct contact with corresponding parts of the inner gate insulating layer, respectively.

20. The semiconductor device of claim 16, wherein
the blocking pattern has a semi-oval profile, and
a width of the blocking pattern decreases as a downward distance from the top surface of the blocking pattern increases in a vertical direction.
